(19) United States
(12) Patent Application Publication
(10) Pub. No.: US 2026/0075922 A1
(43) Pub. Date: Mar. 12, 2026

(54) SEMICONDUCTOR DEVICE WITH AIR SPACERS AND METHOD FOR FABRICATING THE SAME

(71) Applicant: NANYA TECHNOLOGY CORPORATION, NEW TAIPEI CITY (TW)

(72) Inventor: KUO-HUI SU, NEW TAIPEI CITY (TW)

(21) Appl. No.: 18/916,450

(22) Filed: Oct. 15, 2024

Related U.S. Application Data
(62) Division of application No. 18/829,733, filed on Sep. 10, 2024.

(51) Int. Cl. H01L 29/49; H01L 21/02; H01L 21/762; H01L 29/51; H01L 29/66

(52) U.S. Cl. CPC H10D 64/679; H10D 64/018; H10D 64/021; H10D 64/661; H10D 64/68; H10P 14/6548; H10W 10/014; H10W 10/17

(57) ABSTRACT

The present application discloses a semiconductor device and a method for fabricating the semiconductor device. The semiconductor device includes a substrate; a gate structure on the substrate; a plurality of inner spacer layers on sidewalls of the gate structure; a plurality of outer spacer layers on the plurality of inner spacer layers; a plurality of air gaps between the inner spacer layers and the outer spacer layers; a bottom dielectric layer on the substrate and laterally surrounding the outer spacer layers; a bottom capping layer on the bottom dielectric layer, the inner spacer layers, the air gaps, the outer spacer layers, and the gate structure; a conductive layer on the bottom capping layer and including a plurality of conductive wires; a top capping layer positioned on the conductive layer; and a plurality of air spacers positioned between the conductive wires.

### CROSS-REFERENCE TO RELATED APPLICATION

This application is a divisional application of U.S. Non-Provisional application Ser. No. 18/829,733 filed Sep. 10, 2024, which is incorporated herein by reference in its entirety.

### TECHNICAL FIELD

The present disclosure relates to a semiconductor device and a method for fabricating the semiconductor device, and more particularly, to a semiconductor device with air spacers and a method for fabricating the semiconductor device with the air spacers.

### DISCUSSION OF THE BACKGROUND

Semiconductor devices are used in a variety of electronic applications, such as personal computers, cellular telephones, digital cameras, and other electronic equipment. The dimensions of semiconductor devices are continuously being scaled down to meet the increasing demand of computing ability. However, a variety of issues arise during the scaling-down process, and such issues are continuously increasing. Therefore, challenges remain in achieving improved quality, yield, performance, and reliability and reduced complexity.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor device including a substrate; a gate structure positioned on the substrate; a plurality of inner spacer layers positioned on sidewalls of the gate structure; a plurality of outer spacer layers positioned on the plurality of inner spacer layers; a plurality of air gaps positioned between the plurality of inner spacer layers and the plurality of outer spacer layers; a bottom dielectric layer positioned on the substrate and laterally surrounding the plurality of outer spacer layers; a bottom capping layer positioned on the bottom dielectric layer, the plurality of inner spacer layers, the plurality of air gaps, the plurality of outer spacer layers, and the gate structure; a conductive layer positioned on the bottom capping layer and including a plurality of conductive wires; a top capping layer positioned on the conductive layer; and a plurality of air spacers positioned between the plurality of conductive wires.

Another aspect of the present disclosure provides a semiconductor device including a substrate and a gate structure positioned on the substrate; a plurality of inner spacer layers positioned on sidewalls of the gate structure and a plurality of outer spacer layers positioned on the plurality of inner spacer layers; a plurality of air gaps positioned between the plurality of inner spacer layers and the plurality of outer spacer layers; a plurality of recesses recessed from a top surface of the substrate, adjacent to the gate structure, and defining a channel region between the plurality of recesses and under the gate structure; a bottom dielectric layer positioned on the substrate, filling the plurality of recesses, and laterally surrounding the plurality of outer spacer layers; a bottom capping layer positioned on the bottom dielectric layer, the plurality of inner spacer layers, the plurality of air gaps, the plurality of outer spacer layers, and the gate structure; a conductive layer positioned on the bottom capping layer and including a plurality of conductive wires; a top capping layer positioned on the conductive layer; and a plurality of air spacers positioned between the plurality of conductive wires.

Another aspect of the present disclosure provides a method for fabricating a semiconductor device including providing a substrate and forming a gate structure on the substrate; forming a plurality of inner spacer layers on sidewalls of the gate structure, forming a plurality of sacrificial spacer layers on the plurality of inner spacer layers, and forming a plurality of outer spacer layers on the plurality of sacrificial spacer layers; forming a bottom dielectric layer covering the gate structure and the plurality of outer spacer layers; performing a first planarization process to expose the plurality of sacrificial spacer layers, and removing the plurality of sacrificial spacer layers to form a plurality of temporary spaces; forming a bottom capping layer on the bottom dielectric layer and sealing the plurality of temporary spaces to form a plurality of air gaps; forming a conductive layer including a plurality of conductive wires on the bottom capping layer; and forming a plurality of air spacers within the conductive layer.

Due to the design of the semiconductor device of the present disclosure, electromagnetic noise and crosstalk between the conductive lines can be significantly reduced by the air spacers formed along lateral directions (i.e., sidewalls) of the conductive wires. In addition, electromagnetic noise and crosstalk between the gate structure and the conductive elements can also be significantly reduced by the air gaps formed between the inner spacer layers and the outer spacer layers. As a result, the performance of the semiconductor device may be improved.

The foregoing has outlined rather broadly the features and technical advantages of the present disclosure in order that the detailed description of the disclosure that follows may be better understood. Additional features and advantages of the disclosure will be described hereinafter and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 illustrates, in a flowchart diagram form, a method for fabricating a semiconductor device in accordance with one embodiment of the present disclosure;

FIGS. 2 to 20 illustrate, in schematic cross-sectional view diagrams, a flow for fabricating the semiconductor device in accordance with one embodiment of the present disclosure; and

FIGS. 21 to 42 illustrate, in schematic cross-sectional view diagrams, a flow for fabricating a semiconductor device in accordance with another embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

It should be understood that, although the terms first, second, etc. may be used herein to describe various elements, these elements should not be limited by these terms. Unless indicated otherwise, these terms are only used to distinguish one element from another element. Thus, for example, a first element, a first component or a first section discussed below could be termed a second element, a second component or a second section without departing from the teachings of the present disclosure.

Unless the context indicates otherwise, terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to reflect this meaning. For example, items described as “substantially the same,” “substantially equal,” or “substantially planar,” may be exactly the same, equal, or planar, or may be the same, equal, or planar within acceptable variations that may occur, for example, due to manufacturing processes.

In the present disclosure, a semiconductor device generally means a device which can function by utilizing semiconductor characteristics, and an electro-optic device, a light-emitting display device, a semiconductor circuit, and an electronic device are all included in the category of the semiconductor device.

It should be noted that, in the description of the present disclosure, above (or up) corresponds to the direction of the arrow of the direction Z, and below (or down) corresponds to the opposite direction of the arrow of the direction Z.

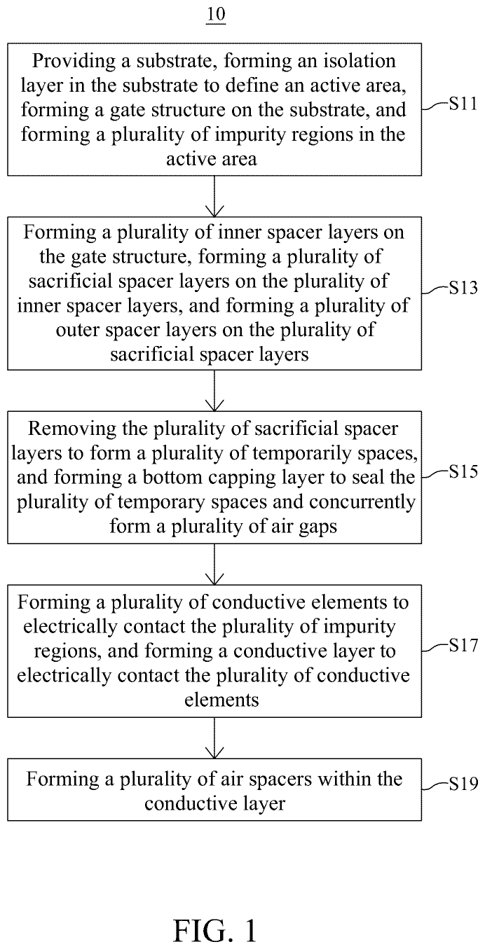

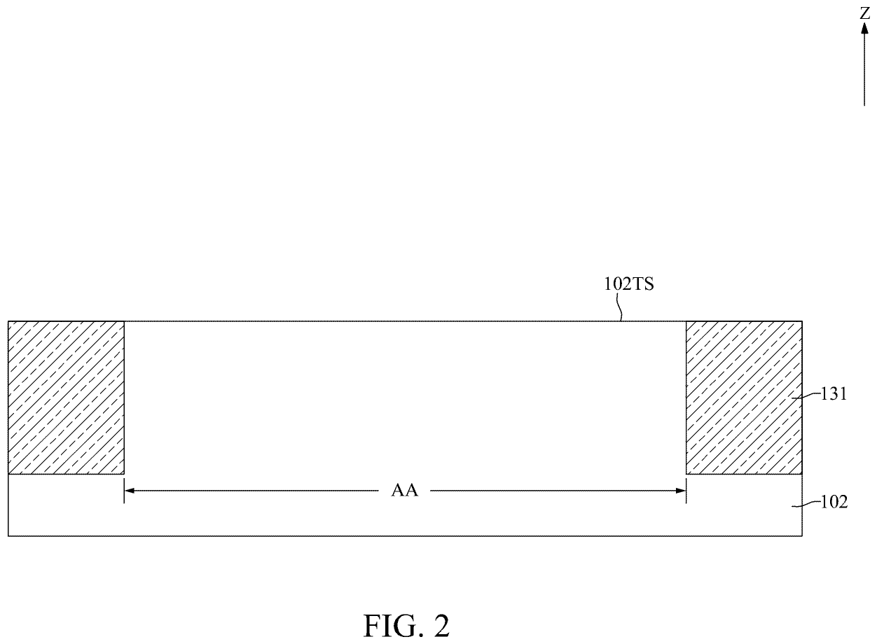

FIG. 1 illustrates, in a flowchart diagram form, a method 10 for fabricating a semiconductor device 100A in accordance with one embodiment of the present disclosure. FIGS. 2 to 20 illustrate, in schematic cross-sectional view diagrams, a flow for fabricating the semiconductor device 100A in accordance with one embodiment of the present disclosure.

With reference to FIGS. 1 to 5, at step S11, a substrate 102 may be provided, an isolation layer 131 may be formed in the substrate 102 to define an active area AA, a gate structure 200 may be formed on the substrate 102, and a plurality of impurity regions 301 may be formed in the active area AA.

With reference to FIG. 2, the substrate 102 may be a bulk semiconductor substrate that is composed entirely of at least one semiconductor material; the bulk semiconductor substrate does not contain any dielectrics, insulating layers, or conductive features. The bulk semiconductor substrate may be formed of, for example, an elementary semiconductor, such as silicon or germanium; a compound semiconductor, such as silicon germanium, silicon carbide, gallium arsenide, gallium phosphide, indium phosphide, indium arsenide, indium antimonide, or other III-V compound semiconductor or II-VI compound semiconductor; or combinations thereof.

With reference to FIG. 2, the isolation layer 131 may be formed in the substrate 102. A series of deposition processes may be performed to deposit a pad oxide layer (not shown) and a pad nitride layer (not shown) on the substrate 102. A photolithography process and a subsequent etching process, such as an anisotropic dry etching process, may be performed to form trenches penetrating through the pad oxide layer, the pad nitride layer, and extending to the substrate 102. An insulating material may be deposited into the trenches and a planarization process, such as chemical mechanical polishing, may be subsequently performed until the top surface of the substrate 102 is exposed to remove excess filling material, provide a substantially flat surface for subsequent processing steps, and concurrently form the isolation layer 131. The insulating material may be, for example, silicon oxide or other applicable insulating materials. The isolation layer 131 may define the active area AA in the substrate 102.

It should be noted that, in the description of the present disclosure, a surface of an element (or a feature) located at the highest vertical level along the Z axis is referred to as a top surface of the element (or the feature). A surface of an element (or a feature) located at the lowest vertical level along the Z axis is referred to as a bottom surface of the element (or the feature).

It should be noted that the active area AA may include a portion of the substrate 102 and a space above the portion of the substrate 102. Describing an element as being disposed on the active area AA means that the element is disposed on a top surface 102TS of the portion of the substrate 102. Describing an element as being disposed in (or within) the active area AA means that the element is disposed in the portion of the substrate 102; however, a top surface of the element may be even or coplanar with the top surface 102TS of the portion of the substrate 102. Describing an element as being disposed above the active area AA means that the element is disposed above the top surface 102TS of the portion of the substrate 102.

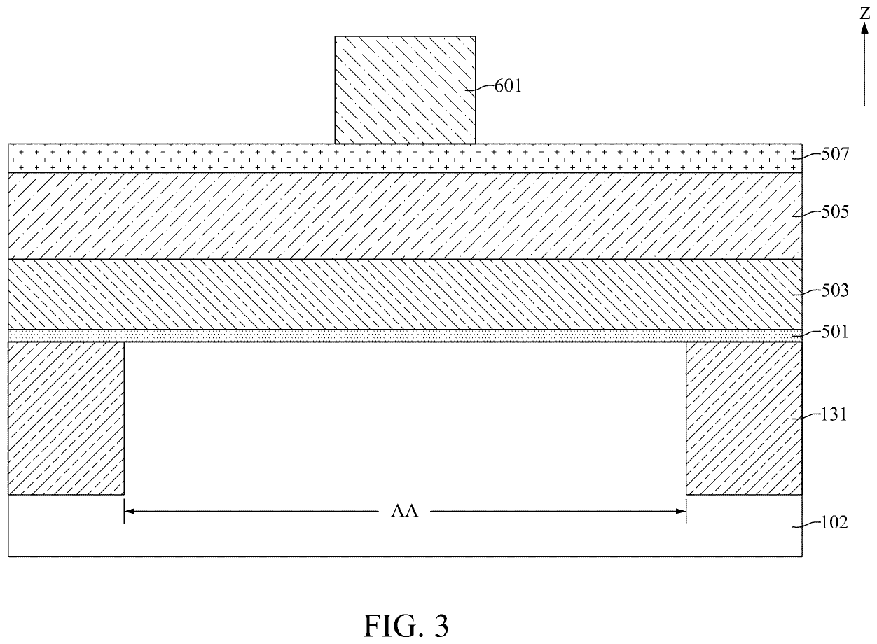

With reference to FIG. 3, a layer of first insulating material 501 may be formed on the substrate 102 and covering the active area AA. In some embodiments, the first insulating material 501 may include, for example, a high-k material, silicon oxide, or combinations thereof. In some embodiments, the layer of first insulating material 501 may be formed by, for example, chemical vapor deposition, atomic layer deposition, or other applicable deposition processes.

In some embodiments, the high-k material may include a hafnium-containing material. The hafnium-containing material may be, for example, hafnium oxide, hafnium silicon oxide, hafnium silicon oxynitride, or a combination thereof. In some embodiments, the high-k material may be, for example, lanthanum oxide, lanthanum aluminum oxide, zirconium oxide, zirconium silicon oxide, zirconium silicon oxynitride, aluminum oxide or a combination thereof.

With reference to FIG. 3, a layer of first conductive material 503 may be formed on the layer of first insulating material 501. In some embodiments, the first conductive material 503 may include, for example, doped polycrystalline silicon, doped polycrystalline germanium, doped polycrystalline silicon germanium, or a combination thereof. In some embodiments, the layer of first conductive material 503 may be doped by n-type dopants or p-type dopants. The n-type dopants may include, for example, antimony, arsenic, and phosphorus. The p-type dopants may include, for example, boron, aluminum, gallium, and indium. In some embodiments, the layer of first conductive material 503 may be formed by, for example, chemical vapor deposition, plasma-enhanced chemical vapor deposition, or other applicable deposition processes.

With reference to FIG. 3, a layer of second conductive material 505 may be formed on the layer of first conductive material 503. In some embodiments, the second conductive material 505 may include, for example, tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof. In some embodiments, the layer of second conductive material 505 may be formed by, for example, physical vapor deposition, sputtering, electroplating, electroless plating, chemical vapor deposition, atomic layer deposition, or other applicable deposition processes.

With reference to FIG. 3, a layer of second insulating material 507 may be formed on the layer of second conductive material 505. In some embodiments, the second insulating material 507 may include, for example, an oxide, a nitride, or an oxynitride. In some embodiments, the second insulating material 507 may include silicon nitride or silicon oxide. In some embodiments, the layer of second insulating material 507 may be formed by, for example, chemical vapor deposition or other applicable deposition processes.

With reference to FIG. 3, a first mask layer 601 may be formed on the layer of second insulating material 507. In some embodiments, the first mask layer 601 may be a photoresist layer. In some embodiments, the first mask layer 601 may include the pattern of the gate structure 200.

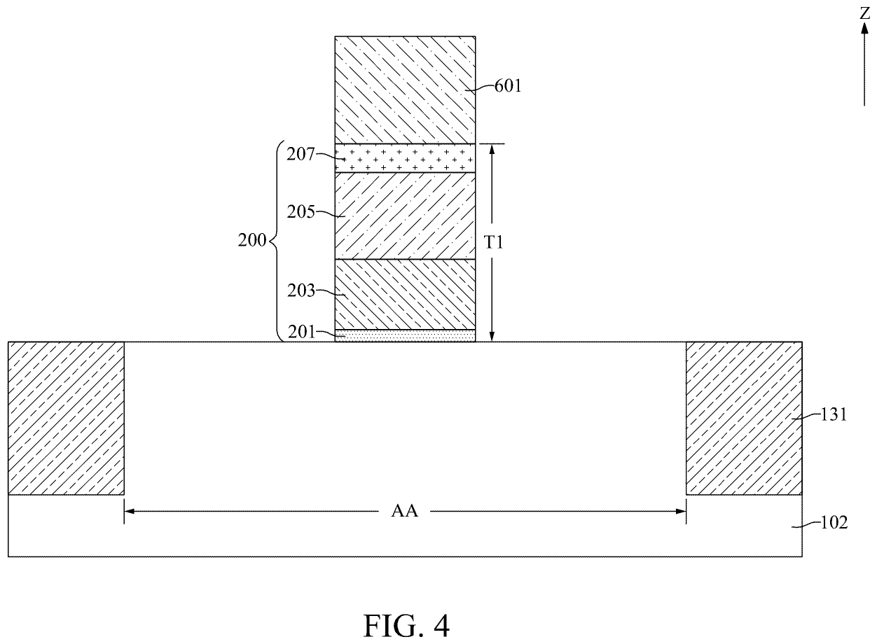

With reference to FIG. 4, an etching process may be performed using the first mask layer 601 as the mask to remove portions of the second insulating material 507, the second conductive material 505, the first conductive material 503, and the first insulating material 501. In some embodiments, the etching process may be an anisotropic dry etching process. The remaining first insulating material 501 may be referred to as a gate dielectric layer 201. The remaining first conductive material 503 may be referred to as a gate bottom conductive layer 203. The gate bottom conductive layer 203 may be disposed on the gate dielectric layer 201. The remaining second conductive material 505 may be referred to as a gate top conductive layer 205. The gate top conductive layer 205 may be disposed on the gate bottom conductive layer 203. The remaining second insulating material 507 may be referred to as a gate capping layer 207. The gate capping layer 207 may be disposed on the gate top conductive layer 205. In some embodiments, the width of the gate capping layer 207, the width of the gate top conductive layer 205, the width of the gate bottom conductive layer 203, and the width of the gate dielectric layer 201 may be substantially the same. The gate dielectric layer 201, the gate bottom conductive layer 203, the gate top conductive layer 205, and the gate capping layer 207 together configure the gate structure 200. In some embodiments, the thickness T1 of the gate structure 200 may be between about 70 nm and about 55 nm.

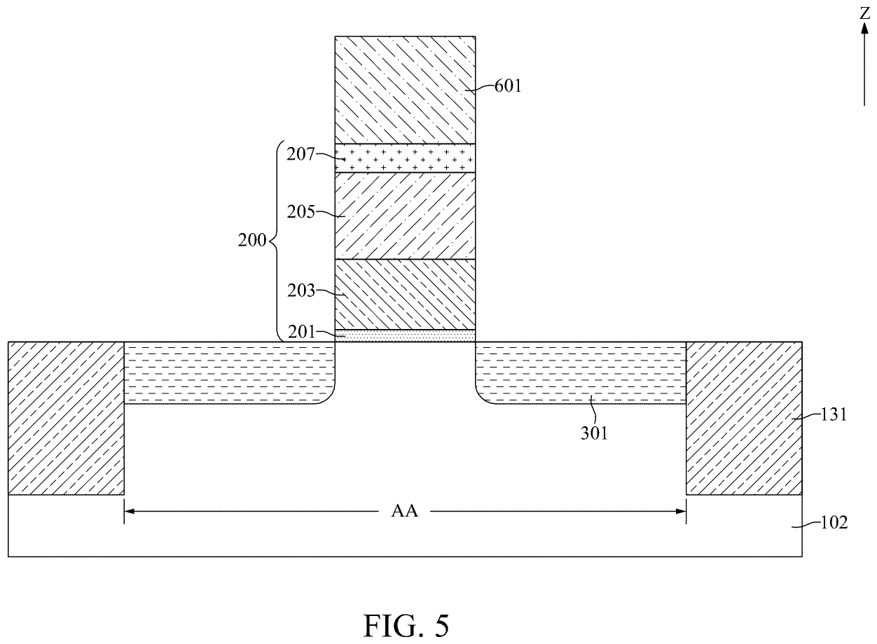

With reference to FIG. 5, in some embodiments, the plurality of impurity regions 301 may be formed within the active area AA by an implantation process. That is, the plurality of impurity regions 301 may be turned from a portion of the substrate 102. The dopants of the implantation process may include p-type impurities (dopants) or n-type impurities (dopants). The p-type impurities may be added to an intrinsic semiconductor to create deficiencies of valence electrons. In a silicon-containing substrate, examples of p-type dopants, i.e., impurities include but are not limited to boron, aluminum, gallium, and indium. The n-type impurities may be added to an intrinsic semiconductor to contribute free electrons to the intrinsic semiconductor. In a silicon-containing substrate, examples of n-type dopants, i.e., impurities, include but are not limited to antimony, arsenic, and phosphorus. In some embodiments, the dopant concentration of the plurality of impurity regions 301 may be between about 1E19 atoms/cm\hat{ }3 and about 1E21 atoms/cm\hat{ }3. After the implantation process, the plurality of impurity regions 301 may have an electrical type such as n-type or p-type.

In some embodiments, an anneal process may be performed to activate the plurality of impurity regions 301. The temperature of the anneal process may be between about 800° C. and about 1250° C. The anneal process may have a process duration between about 1 millisecond and about 500 milliseconds. The anneal process may be, for example, a rapid thermal anneal, a laser spike anneal, or a flash lamp anneal.

With reference to FIG. 1 and FIGS. 6 to 8, at step S13, a plurality of inner spacer layers 401 may be formed on the gate structure 200, a plurality of sacrificial spacer layers 403 may be formed on the plurality of inner spacer layers 401, and a plurality of outer spacer layers 405 may be formed on the plurality of sacrificial spacer layers 403.

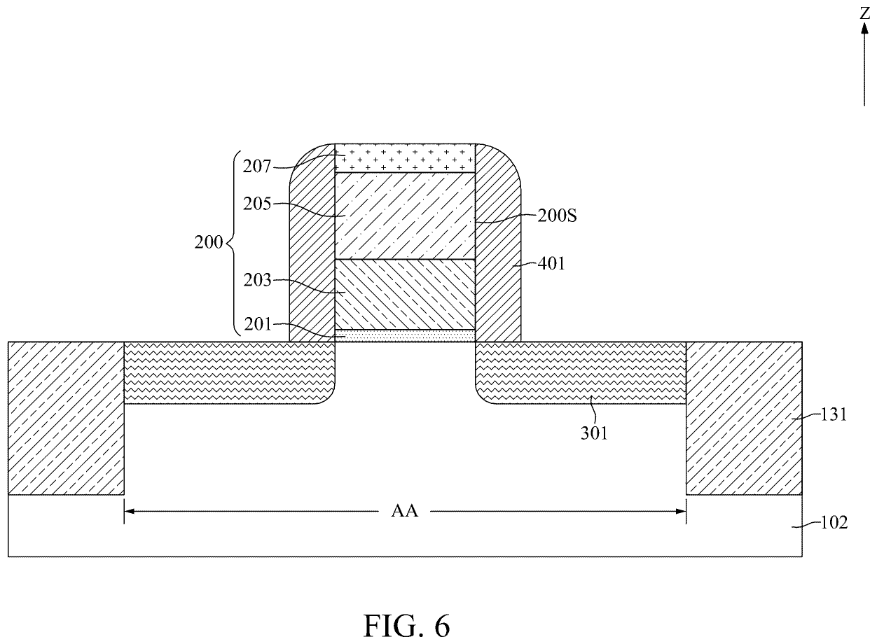

With reference to FIG. 6, the plurality of inner spacer layers 401 may be conformally formed on the sidewalls 200S of the gate structure 200 and on the plurality of impurity regions 301. In some embodiments, the plurality of inner spacer layers 401 may be formed of the same material as the gate capping layer 207. In some embodiments, the inner spacer layer 401 may be formed of a carbon-containing material. The carbon-containing material may include high density carbon (HDC), silicon carbide (SiC) or silicon carbonitride (SiCN). In some embodiments, the plurality of inner spacer layers 401 may include, for example, a nitride or an oxynitride. In some embodiments, the plurality of inner spacer layers 401 may include silicon nitride, silicon oxynitride, or silicon nitride oxide. In some embodiments, the plurality of inner spacer layers 401 may be formed by, for example, chemical vapor deposition or other applicable deposition processes with a subsequent anisotropic etching process.

It should be noted that, in the description of the present disclosure, silicon oxynitride refers to a substance which contains silicon, nitrogen, and oxygen and in which a proportion of oxygen is greater than that of nitrogen. Silicon nitride oxide refers to a substance which contains silicon, oxygen, and nitrogen and in which a proportion of nitrogen is greater than that of oxygen.

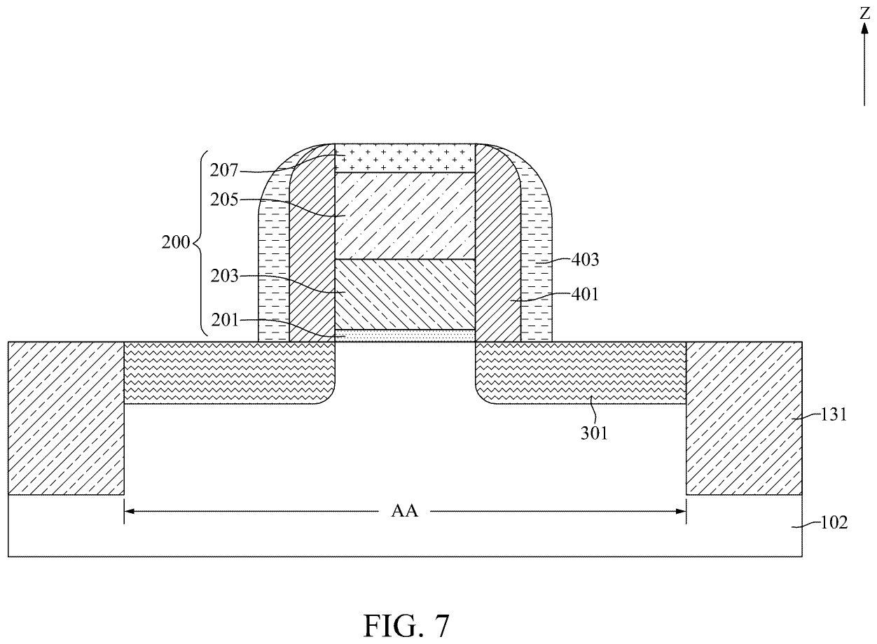

With reference to FIG. 7, the plurality of sacrificial spacer layers 403 may be conformally formed on the plurality of inner spacer layers 401, respectively and correspondingly. The plurality of sacrificial spacer layers 403 may be formed on the plurality of impurity regions 301. In some embodiments, the plurality of sacrificial spacer layers 403 may be formed of a material having etching selectivity to the inner spacer layer 401 and an outer spacer layer 405 which will be illustrated later. For example, the sacrificial spacer layer 403 may be formed of doped silicon oxide, whereas the inner spacer layer 401 may be formed of a carbon-containing material. The carbon-containing material may include high density carbon, silicon carbide or silicon carbonitride.

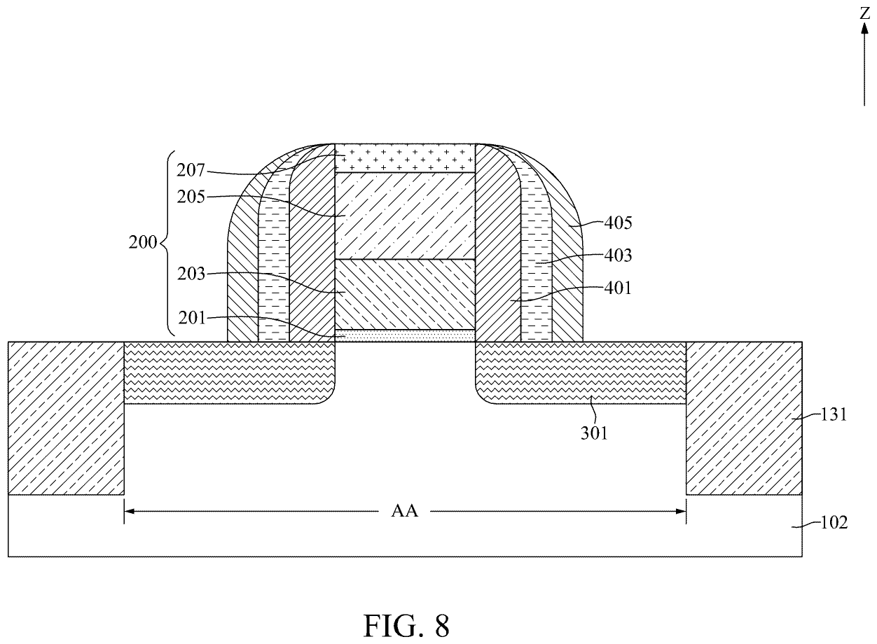

With reference to FIG. 8, the plurality of outer spacer layers 405 may be conformally formed on the plurality of sacrificial spacer layers 403, respectively and correspondingly. The plurality of sacrificial spacer layers 403 may be formed on the plurality of impurity regions 301. In some embodiments, the plurality of outer spacer layers 405 may be formed of the same material as the plurality of inner spacer layers 401. In some embodiments, the plurality of outer spacer layers 405 may include, for example, a nitride or an oxynitride. In some embodiments, the plurality of outer spacer layers 405 may include silicon nitride, silicon oxynitride, or silicon nitride oxide. In some embodiments, the plurality of outer spacer layers 405 may be formed by, for example, chemical vapor deposition or other applicable deposition processes with a subsequent anisotropic etching process.

With reference to FIG. 1 and FIGS. 9 to 12, at step S15, the plurality of sacrificial spacer layers 403 may be removed to form a plurality of temporarily spaces 603, and a bottom capping layer 605 may be formed to seal the plurality of temporary spaces 603 and concurrently form a plurality of air gaps AG.

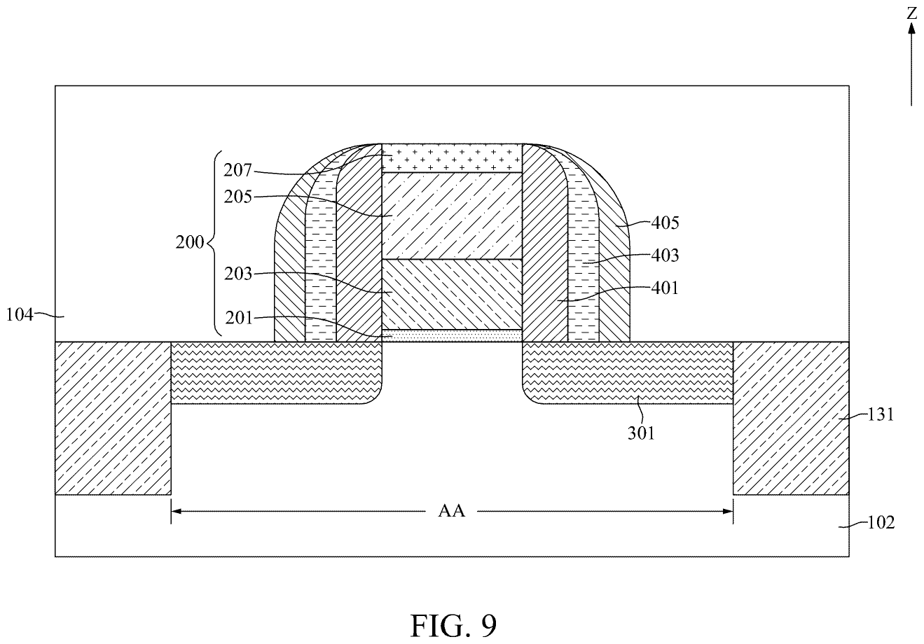

With reference to FIG. 9, a bottom dielectric layer 104 may be formed on the substrate 102 and completely covering the gate structure 200, the plurality of inner spacer layers 401, the plurality of sacrificial spacer layers 403, and the plurality of outer spacer layers 405. In some embodiments, the bottom dielectric layer 104 may be formed of, for example, silicon oxide, borophosphosilicate glass, undoped silicate glass, fluorinated silicate glass, low-k dielectric materials, or a combination thereof. The low-k dielectric materials may have a dielectric constant less than 3.0 or even less than 2.5. In some embodiments, the undoped silicate glass can be expressed as formula SiOₓ. The x may be between 1.4 and 2.1. In some embodiments, the bottom dielectric layer 104 may be formed by, for example, chemical vapor deposition or other applicable deposition processes.

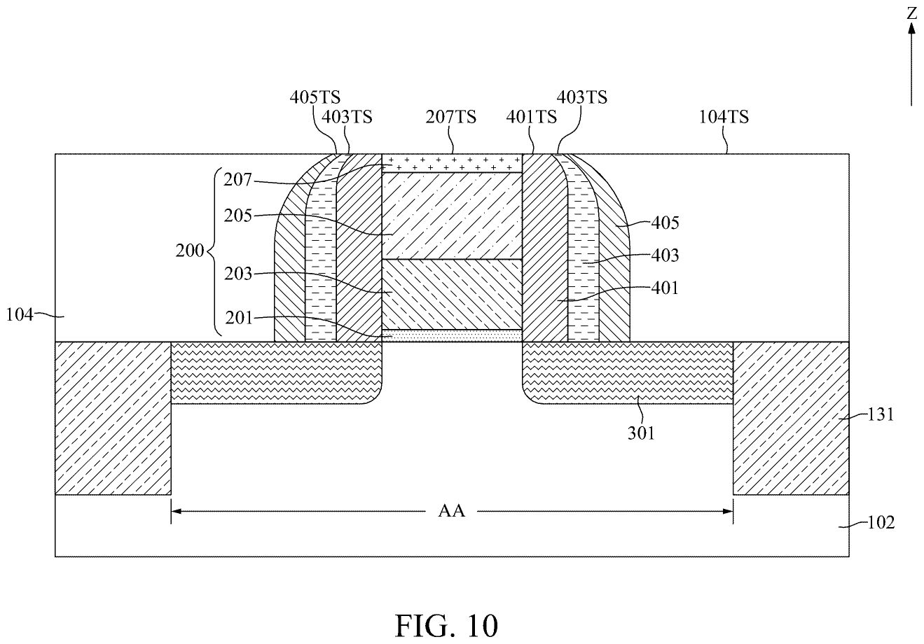

With reference to FIG. 10, a planarization process, such as chemical mechanical polishing, may be performed until the gate capping layer 207, the plurality of inner spacer layers 401, the plurality of sacrificial spacer layers 403, and the plurality of outer spacer layers 405 are exposed. In other words, the top surface 207TS of the gate capping layer 207, the top surface 401TS of the plurality of inner spacer layers 401, the top surface 403TS of the plurality of sacrificial spacer layers 403, the top surface 405TS of the plurality of outer spacer layers 405, and the top surface 104TS of the bottom dielectric layer 104 may be substantially coplanar.

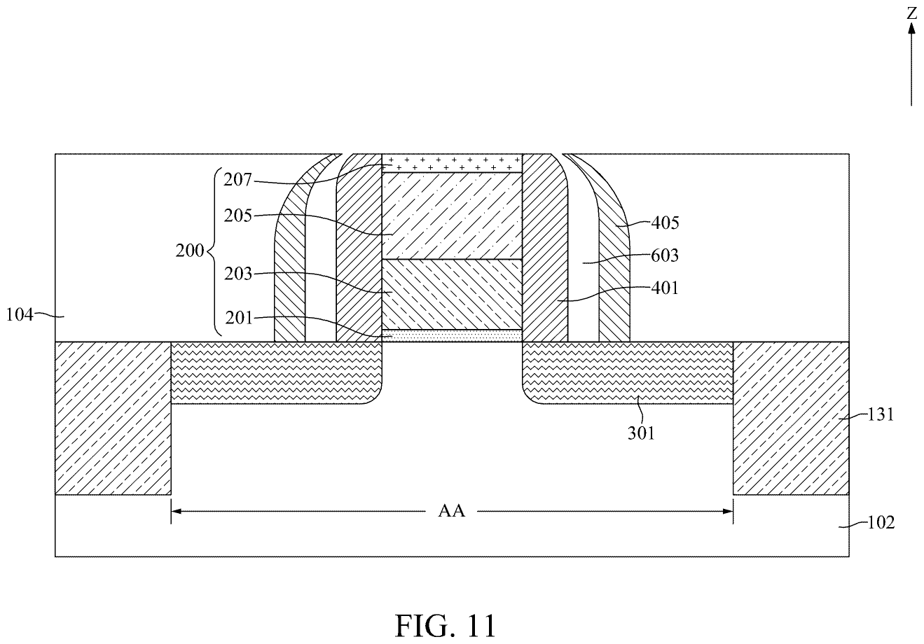

With reference to FIG. 11, the plurality of sacrificial spacer layers 403 may be removed, resulting in the formation of a plurality of temporary spaces 603 in the locations previously occupied by the sacrificial spacer layers. In some embodiments, the plurality of sacrificial spacer layers 403 may be removed by a vapor etching process. In some embodiments, the etchant of the vapor etching process may include vapor hydrofluoric acid (VHF). The etchant used for the etching process may react with the plurality of sacrificial spacer layers 403 from the top ends of the plurality of sacrificial spacer layers 403. Since the sacrificial spacer layer 403 have sufficient etching selectivity with respect to the inner spacer layer 401 and the plurality of outer spacer layers 405, the inner spacer layer 401 and the outer spacer layer 405 may remain substantially intact during the removal of the sacrificial spacer layer 403.

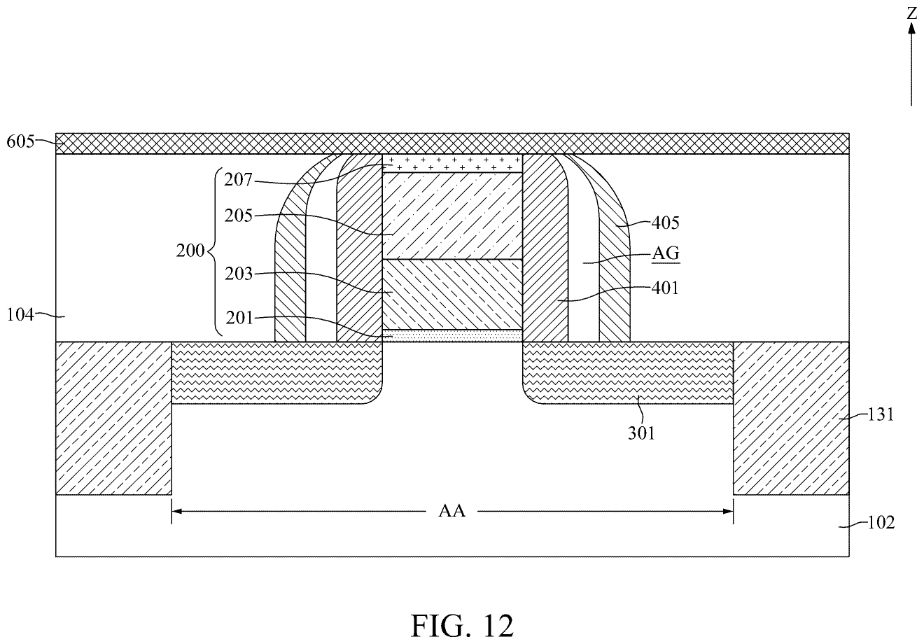

With reference to FIG. 12, the bottom capping layer 605 may be formed on the bottom dielectric layer 104 and seal the plurality of temporary spaces 603. After the formation of the bottom capping layer 605, the plurality of temporary spaces 603 may be turned into the plurality of air gaps AG disposed between the plurality of inner spacer layers 401 and the plurality of outer spacer layers 405. In some embodiments, the bottom capping layer 605 may be formed of, for example, silicon oxide, silicon nitride, or other applicable dielectric materials. In some embodiments, the bottom capping layer 605 may be formed by, for example, chemical vapor deposition or other applicable deposition processes. In some embodiments, a planarization process, such as chemical mechanical polishing, may be performed to remove excess material and provide a substantially flat surface for subsequent processing steps.

Air has the lowest dielectric constant, substantially equal to 1. Electromagnetic noise and crosstalk between the gate structure 200 and the conductive elements 108a, 108b can be significantly reduced by the air gaps AG formed between the inner spacer layers 401 and the outer spacer layers 405.

With reference to FIGS. 1, 13, and 14, at step S17, a plurality of conductive elements 108a, 108b may be formed to electrically contact the plurality of impurity regions 301, and a conductive layer 106 may be formed to electrically contact the plurality of conductive elements 108a, 108b.

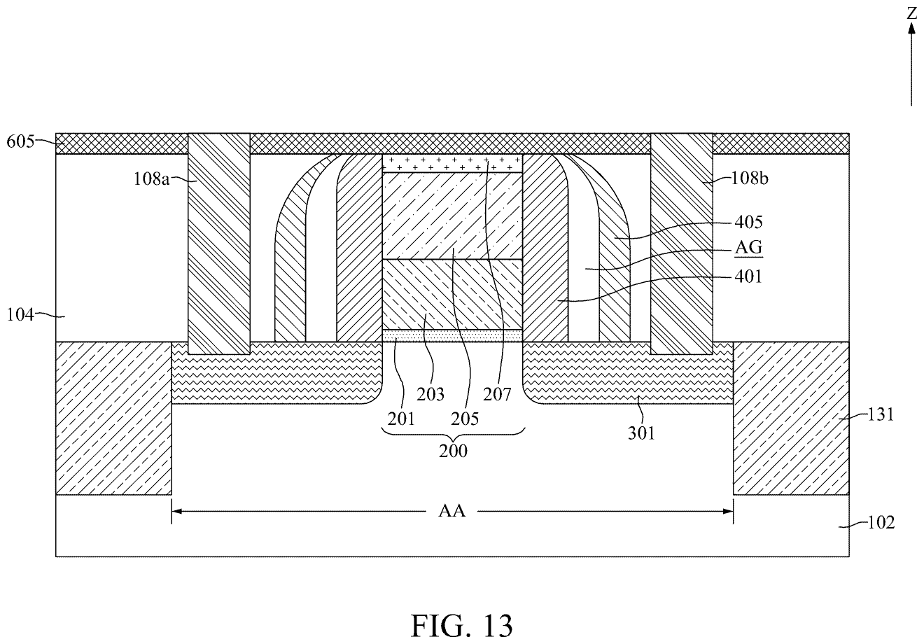

With reference to FIG. 13, the conductive elements 108a, 108b may be formed penetrating the bottom capping layer 605 and the bottom dielectric layer 104. In some embodiments, the conductive elements 108a, 108b may be formed extending to the plurality of impurity regions 301, respectively and correspondingly. In some embodiments, the conductive elements 108a, 108b may electrically contact the plurality of impurity regions 301. In some embodiments, the conductive elements 108a, 108b may be formed on the plurality of impurity regions 301. In some embodiments, the conductive elements 108a, 108b may be formed of, for example, doped polycrystalline silicon, doped polycrystalline germanium, doped polycrystalline silicon germanium, tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof. In some embodiments, the conductive elements 108a, 108b may be formed by, for example, a damascene process.

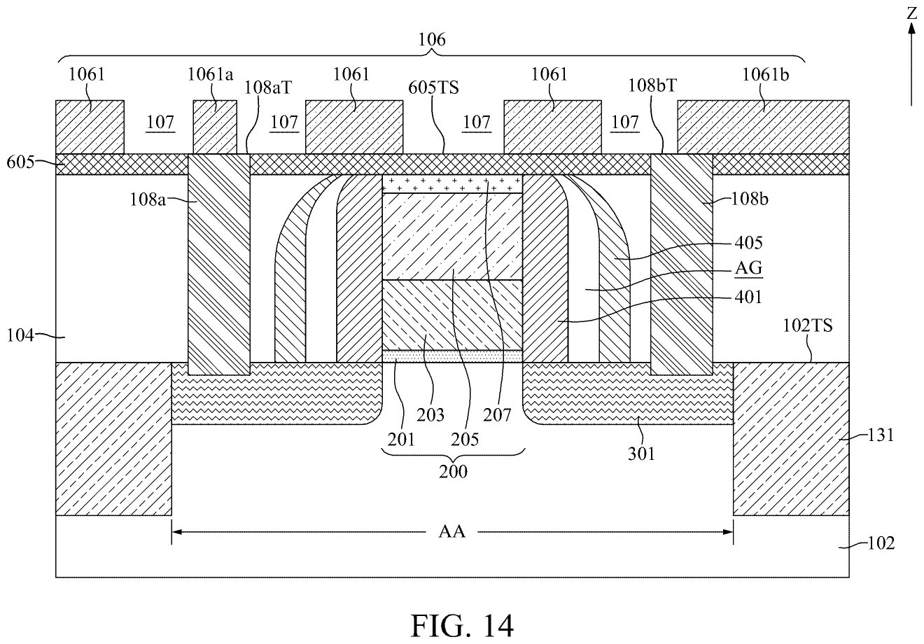

With reference to FIG. 14, the conductive layer 106 may be formed on the bottom capping layer 605 and electrically contact the conductive elements 108a, 108b. In some embodiments, the conductive layer 106 may include a plurality of conductive wires 1061, 1061a, 1061b, which may be signal lines, such as word lines or bit lines, of the semiconductor device 100A. The conductive wires 1061, 1061a, 1061b may be formed of, for example, doped polycrystalline silicon, doped polycrystalline germanium, doped polycrystalline silicon germanium, tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof. In some embodiments, a plurality of gaps 107 (also referred to as first gaps 107) may laterally separate the plurality of conductive wires 1061, 1061a, 1061b.

In some embodiments, the conductive wire 1061a may electrically contact the conductive element 108a, and the conductive wire 1061b may electrically contact the conductive element 108b, as shown in FIG. 14. The top surface 108aT of the conductive element 108a may be substantially coplanar with the top surface 108bT of the conductive element 108b and the top surface 605TS of the bottom capping layer 605. In addition, the top surface 108aT of the conductive element 108a, the top surface 108bTof the conductive element 108b, and the top surface 605TS of the bottom capping layer 605 may have substantially the same elevation with respect to the top surface 102TS of the substrate 102.

In some embodiments, the conductive wire 1061a may partially cover the top surface 108aT of the conductive element 108a. In some embodiments, the conductive wire 1061a may entirely cover the top surface 108aT of the conductive element 108a. In some embodiments, a portion of the conductive wire 1061b may partially cover the top surface 108bT of the conductive element 108b. In some embodiments, the conductive wire 1061b may entirely cover the top surface 108bT of the conductive element 108b.

In some embodiments, the conductive layer 106 may be the bottommost conductive layer (e.g., M0) in an integrated circuit, and one or more dielectric layers including a conductive layer therein can be formed on the bottom capping layer 605. In addition, the conductive layer 106 can be electrically connected to conductive layers disposed in upper dielectric layers through one or more conductive vias (not shown).

With reference to FIG. 1 and FIGS. 15 to 20, at step S19, a plurality of air spacers 132 may be formed within the conductive layer 106.

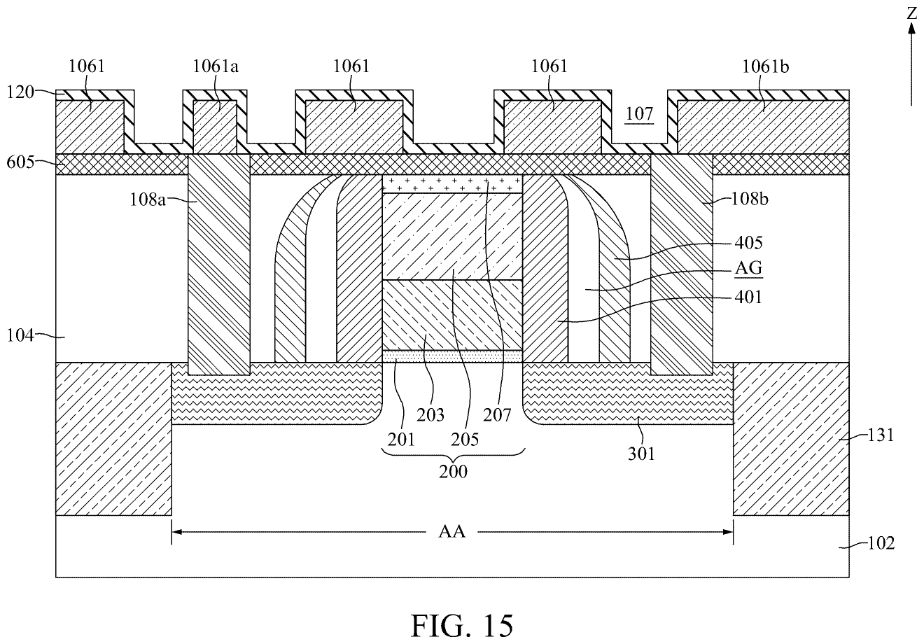

With reference to FIG. 15, a first insulating layer 120 may be conformally formed on the conductive wires 1061, 1061a, and 1061b and the gaps 107 therebetween. In some embodiments, the first insulating layer 120 may be formed by, for example, atomic layer deposition, chemical vapor deposition process, thermal oxidation process, or other applicable deposition processes. In some embodiments, the thickness of the first insulating layer 120 may be substantially the same. The first insulating layer 120 may include an insulating material such as silicon nitride, but the present disclosure is not limited thereto.

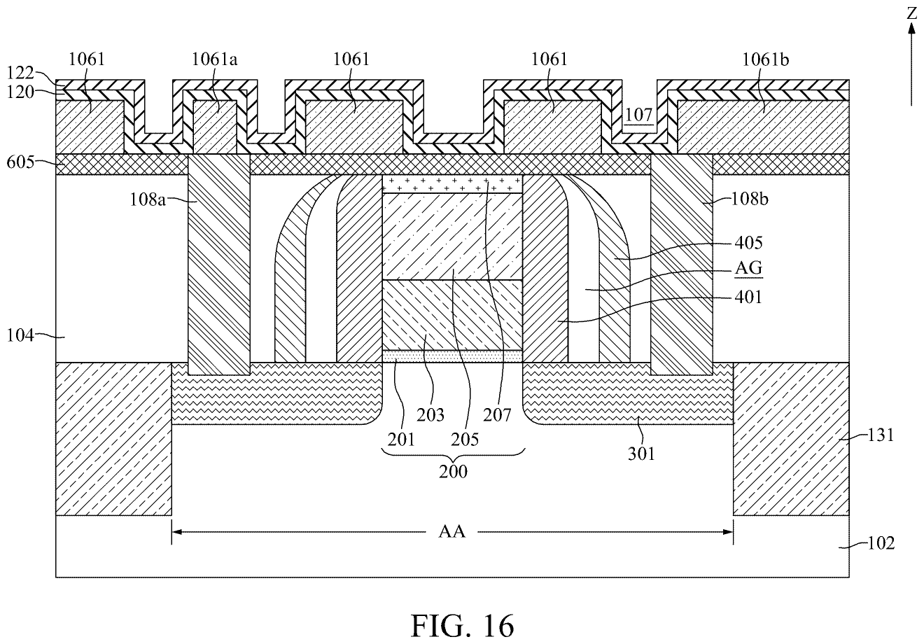

With reference to FIG. 16, a dielectric layer 122 may be conformally formed on the first insulating layer 120. In some embodiments, the dielectric layer 122 may be formed by, for example, atomic layer deposition, chemical vapor deposition process, thermal oxidation process, or other applicable deposition processes. In some embodiments, the thickness of the dielectric layer 122 may be substantially the same. In some embodiments, the dielectric layer 122 may be formed of a material having etching selectivity to the first insulating layer 120. In some embodiments, the dielectric layer 122 may include a dielectric material such as silicon oxide or other suitable material.

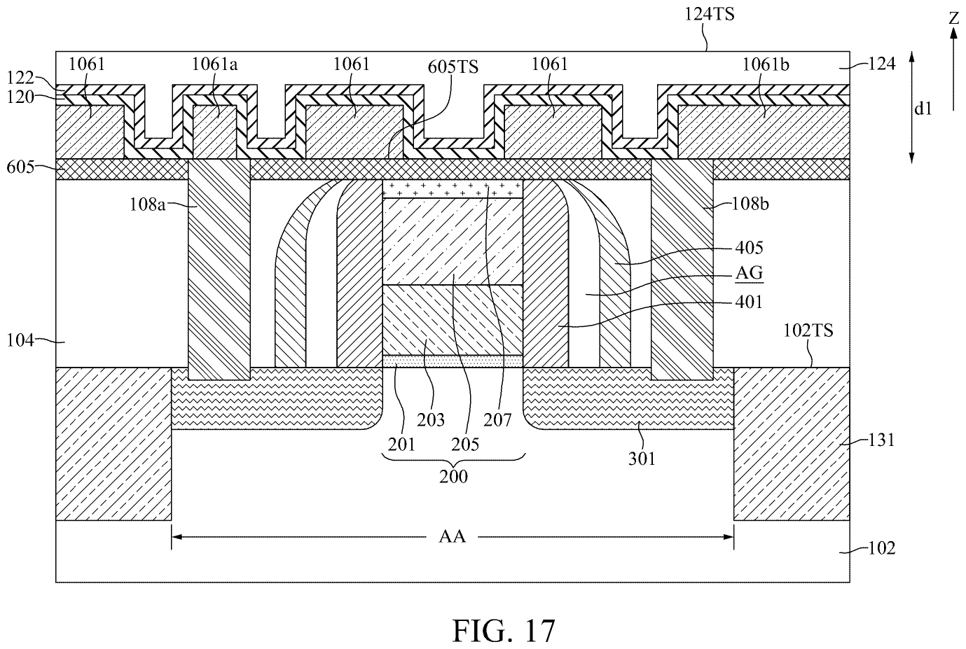

With reference to FIG. 17, a second insulating layer 124 may be formed on the dielectric layer 122. In some embodiments, the second insulating layer 124 may fill the gaps 107 (as shown in FIG. 16) along lateral directions of the conductive wires 1061, 1061a, 1061b. In addition, the second insulating layer 124 may have a first thickness d1 with respect to the top surface 605TS of the bottom capping layer 605. In some embodiments, the second insulating layer 124 may be formed by chemical vapor deposition process, thermal oxidation process, or other applicable deposition processes. In some embodiments, the second insulating layer 124 may be formed of the same material as the first insulating layer 120. In some embodiments, the second insulating layer 124 may include an insulating material such as silicon nitride, but the present disclosure is not limited thereto.

A planarization process, such as chemical mechanical polishing, may be performed to remove excess material and provide a substantially flat surface for subsequent processing steps. In some embodiments, the top surface 124TS of the second insulating layer 124 may be substantially level and parallel to the top surface 102TS of the substrate 102.

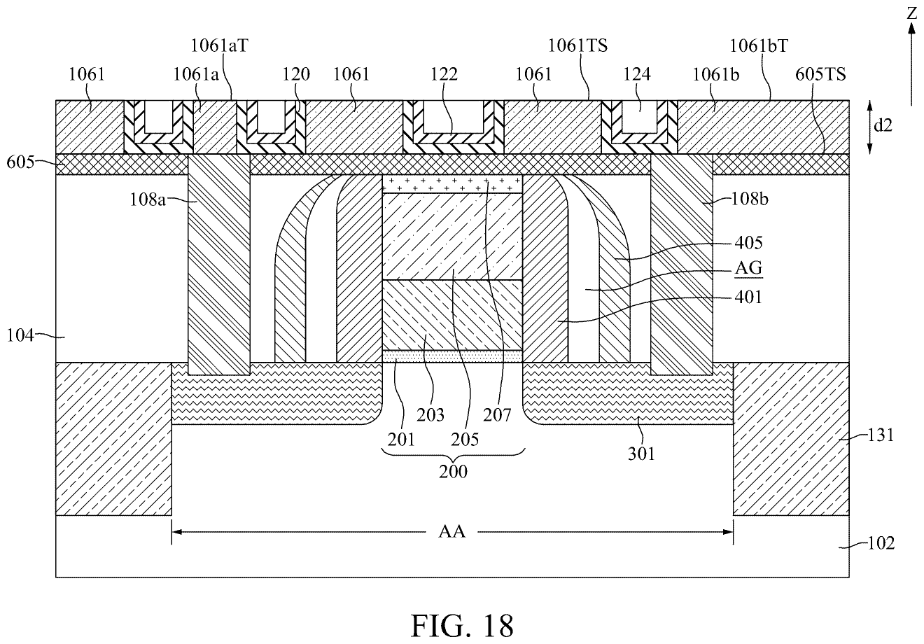

With reference to FIG. 18, the second insulating layer 124 may be further polished to expose the conductive wires 1061, 1061a, and 1061b. In some embodiments, the second insulating layer 124 may be polished using a planarization process, such as chemical mechanical polishing, exposing the top surfaces 1061TS, 1061aT, 1601bT of the conductive wires 1061, 1061a, 1061b. In addition, upper ends of the first insulating layer 120 and the dielectric layer 122 may be also exposed. The polished second insulating layer 124 may have a second thickness d2 with respect to the top surface 605TS of the bottom capping layer 605. The second thickness d2 may be less than the first thickness d1. In some embodiments, the remaining first insulating layer 120 disposed between an adjacent pair of the conductive wires 1061, 1061a, 1061b may have a U-shaped cross-sectional profile. In some embodiments, the remaining dielectric layer 122 disposed between and adjacent pair of the conductive wires 1061, 1061a, 1061b may have a U-shaped cross-sectional profile.

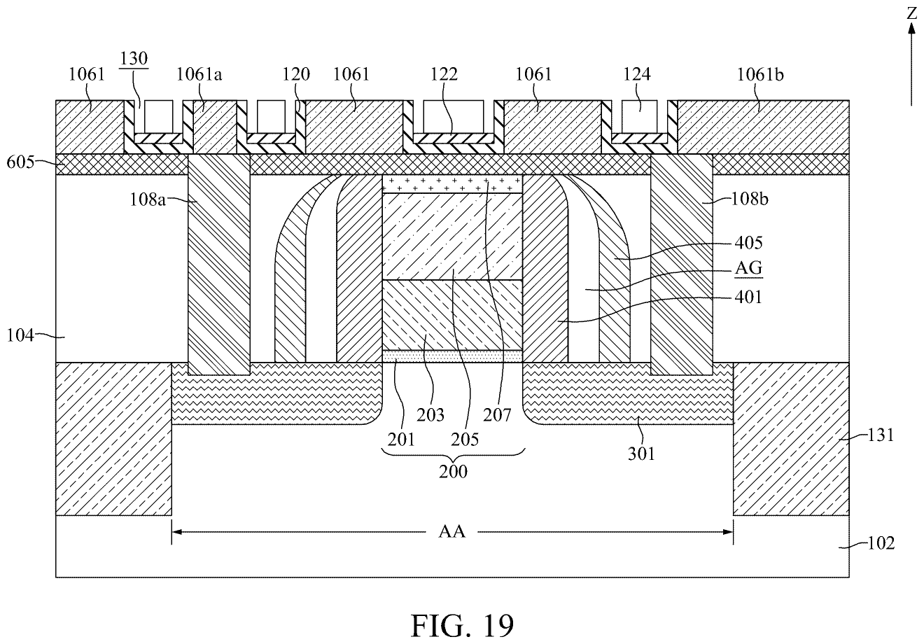

With reference to FIG. 19, the dielectric layer 122 may be partially etched to form a plurality of gaps 130 (also referred to as second gaps 130) between the conductive wires 1061, 1061a, and 1061b. In some embodiments, the gaps 130 can also be referred to as sidewall gaps along lateral directions of the conductive wires 1061, 1061a, 1061b. In some embodiments, the dielectric layer 122 may be etched using a vapor etching process. In some other embodiments, the dielectric layer 122 may be etched using a dry etching or a wet etching process, but the present disclosure is not limited thereto.

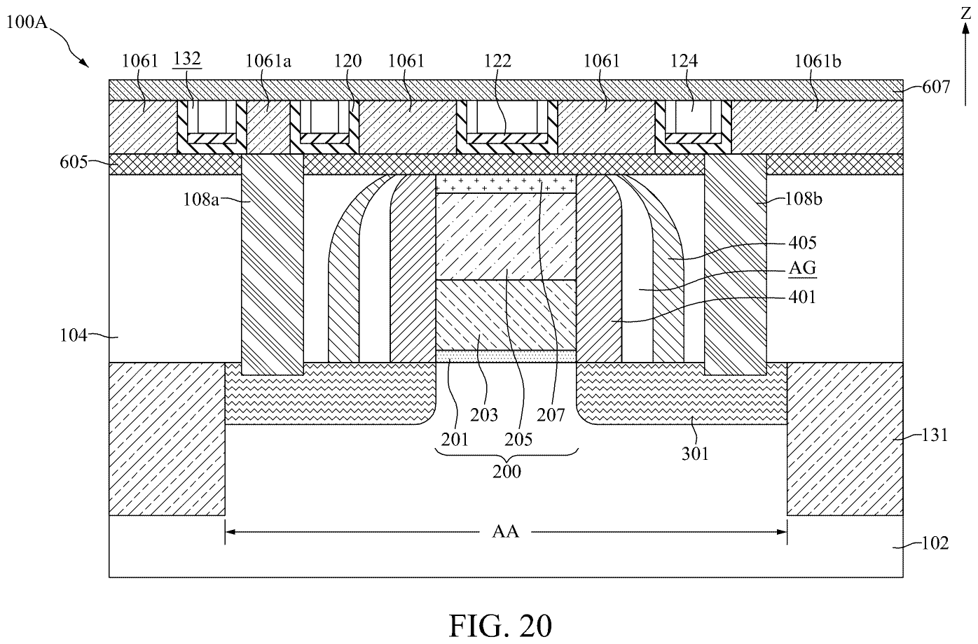

With reference to FIG. 20, a top capping layer 607 may be formed over the conductive layer 106 to seal the gaps 130 and concurrently form the plurality of air spacers 132. In some embodiments, the top capping layer 607 may be formed of the same material as the bottom capping layer 605. In some embodiments, the top capping layer 607 may be formed of, for example, silicon oxide, silicon nitride, or other applicable dielectric materials. In some embodiments, the top capping layer 607 may be formed by, for example, chemical vapor deposition or other applicable deposition processes. In some embodiments, a planarization process, such as chemical mechanical polishing, may be performed to remove excess material and provide a substantially flat surface for subsequent processing steps.

In some embodiments, the air spacers 132 may also be referred to as sidewall spacers of the conductive wires 1061, 1061a, 1061b. For example, each of the air spacers 132 may be sealed (or enclosed) by the top capping layer 607, the remaining first insulating layer 120, the remaining second dielectric layer 122, and the remaining second insulating layer 124.

Air has the lowest dielectric constant, substantially equal to 1. Electromagnetic noise and crosstalk between the conductive lines 1061, 1061a, 1061b can be significantly reduced by the air spacers 132 formed along lateral directions (i.e., sidewalls) of the conductive wires 1061, 1061a, 1061b.

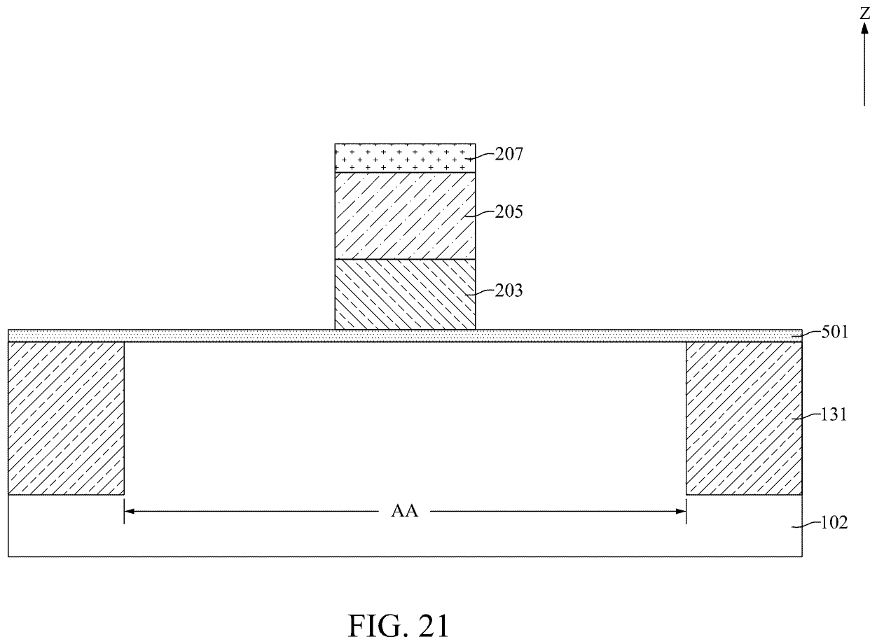

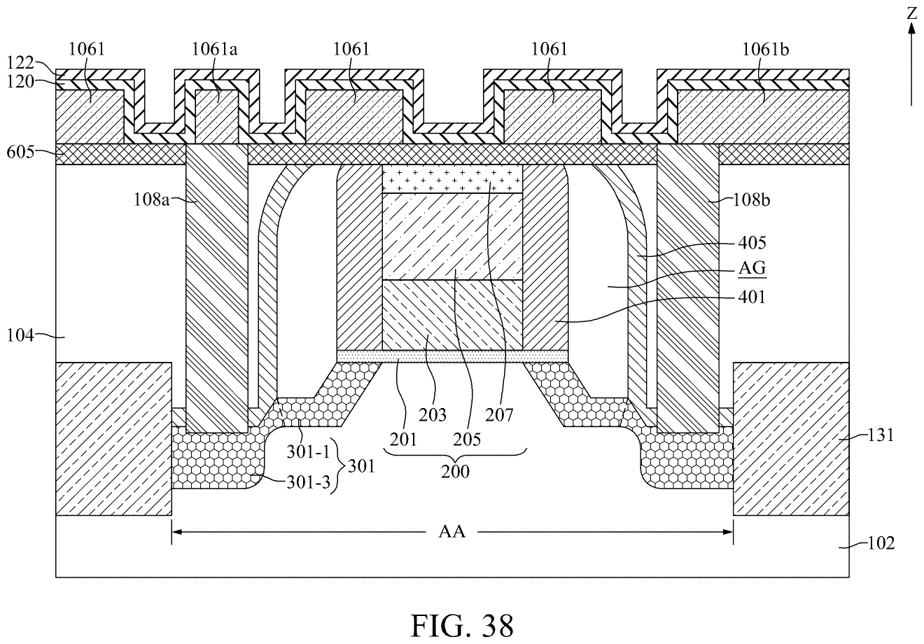

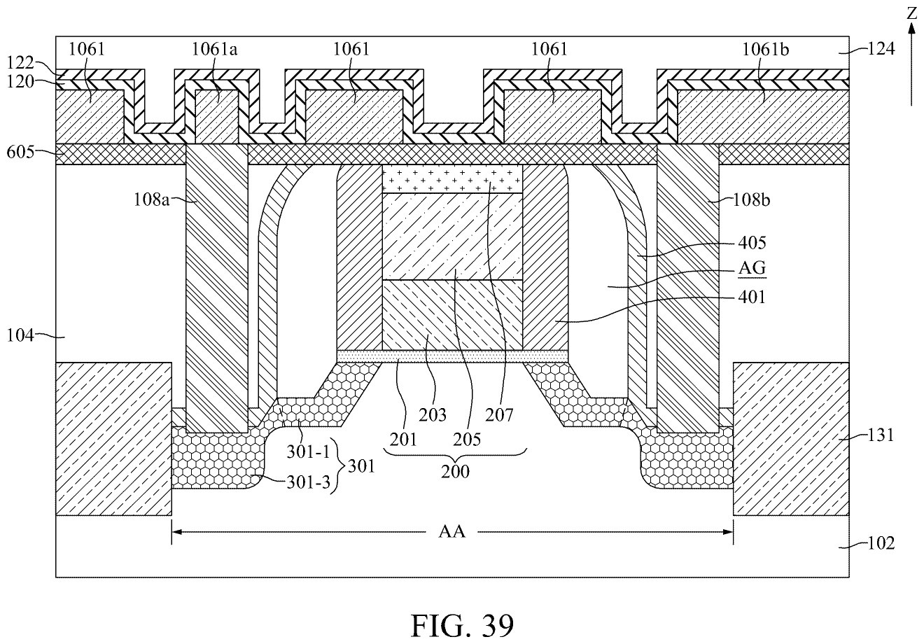

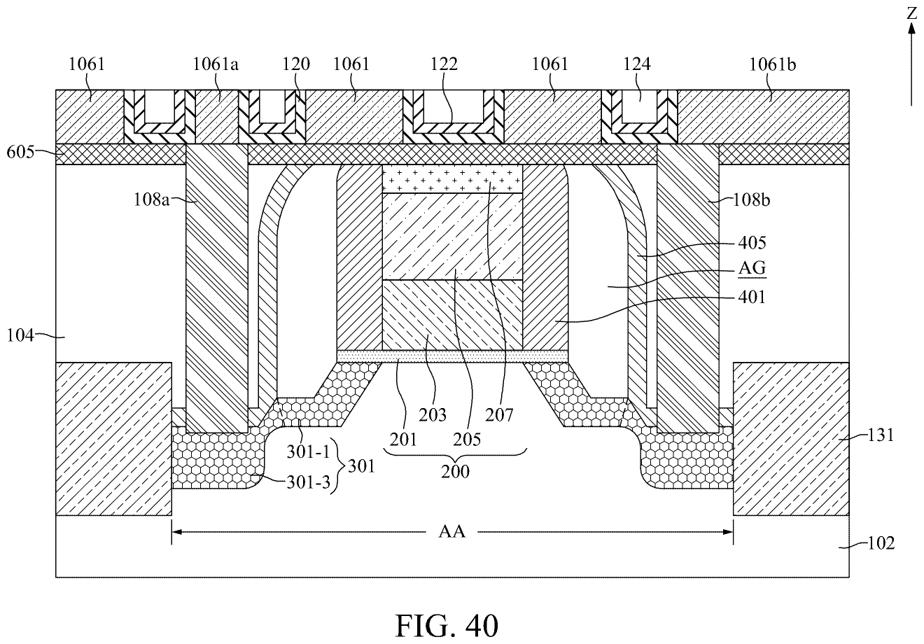

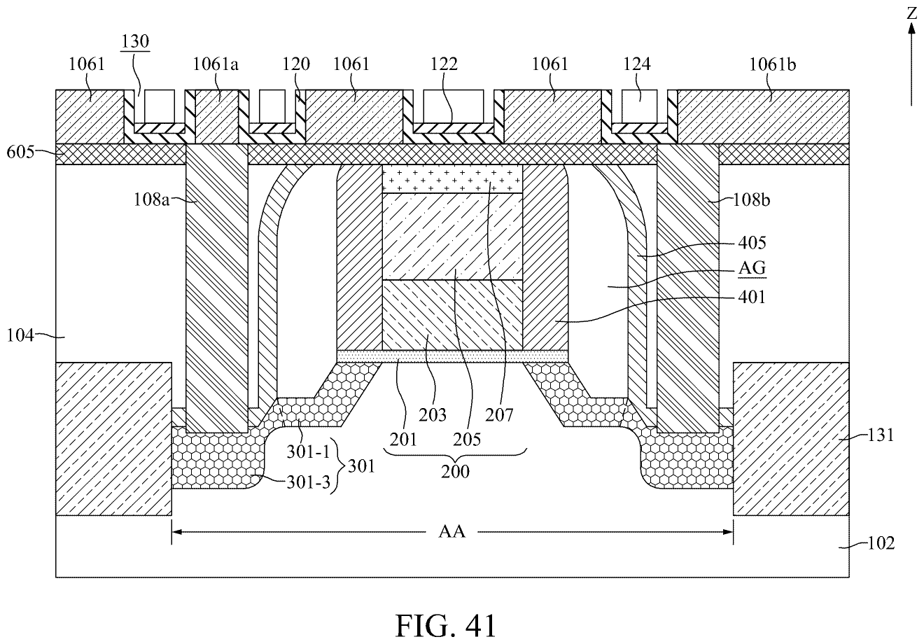

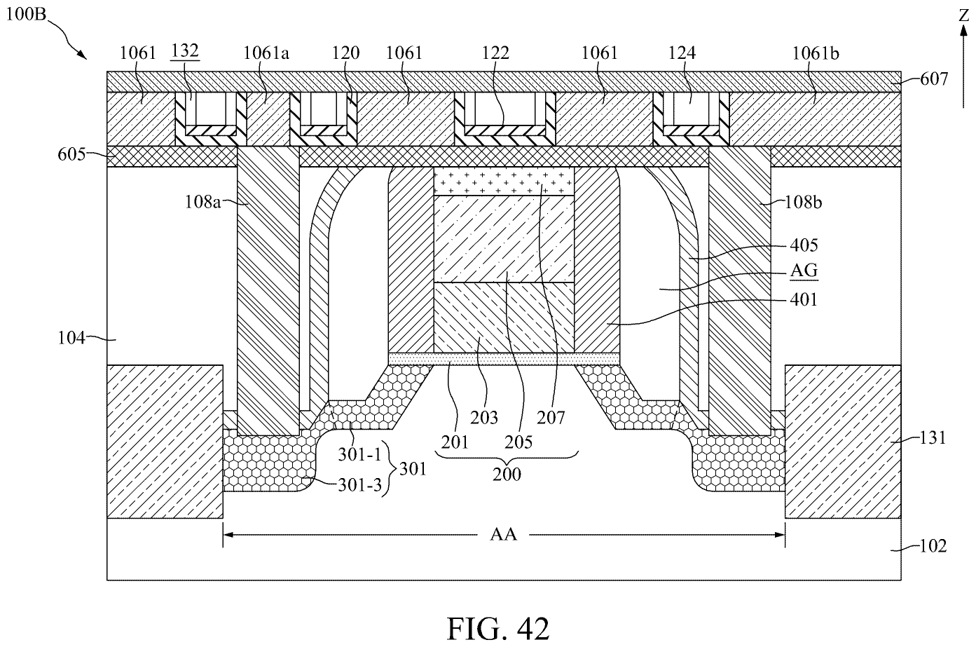

FIGS. 21 to 42 illustrate, in schematic cross-sectional view diagrams, a flow for fabricating a semiconductor device 100B in accordance with another embodiment of the present disclosure.

With reference to FIG. 21, an intermediate semiconductor device may be fabricated with a procedure similar to that illustrated in FIGS. 2 and 3. An etching process may be performed using the first mask layer 601 as the mask to remove portions of the second insulating material 507, the second conductive material 505, and the first conductive material 503. In some embodiments, the etching process may be an anisotropic dry etching process. The remaining first conductive material 503 may be referred to as a gate bottom conductive layer 203. The gate bottom conductive layer 203 may be disposed on the layer of first insulating material 501. The remaining second conductive material 505 may be referred to as a gate top conductive layer 205. The gate top conductive layer 205 may be disposed on the gate bottom conductive layer 203. The remaining second insulating material 507 may be referred to as a gate capping layer 207. The gate capping layer 207 may be disposed on the gate top conductive layer 205. In some embodiments, the width of the gate capping layer 207, the width of the gate top conductive layer 205, and the width of the gate bottom conductive layer 203 may be substantially the same.

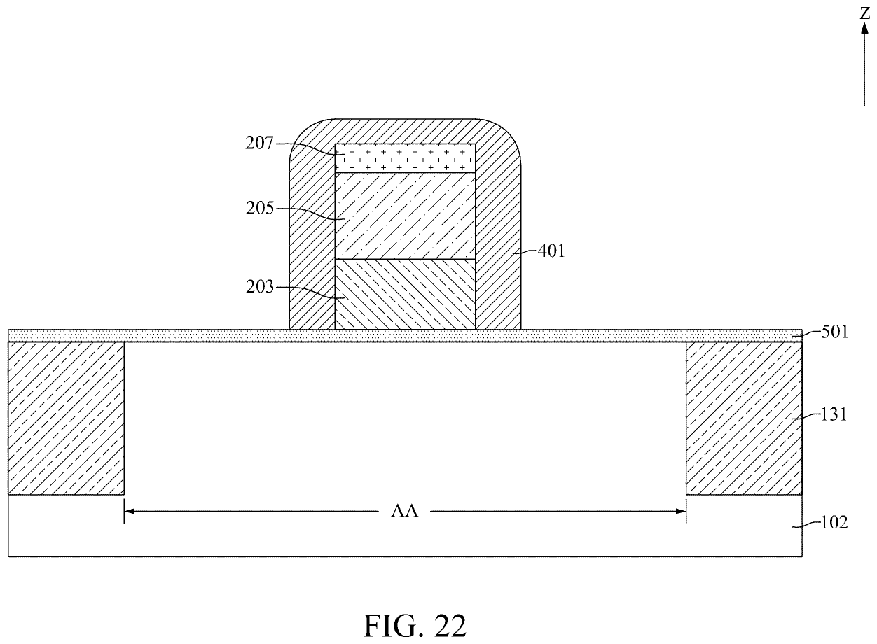

With reference to FIG. 22, the inner spacer layer 401 may be conformally formed to cover the stack of the gate bottom conductive layer 203, the gate top conductive layer 205, and the gate capping layer 207. The inner spacer layer 401 may also cover portions of the layer of first insulating material 501. Stated differently, the inner spacer layer 401 may be formed on the layer of first insulating material 501 and enclose the stack of the gate bottom conductive layer 203, the gate top conductive layer 205, and the gate capping layer 207. In some embodiments, the inner spacer layer 401 may be formed of the same material as the gate capping layer 207. In some embodiments, the inner spacer layer 401 may include, for example, a nitride or an oxynitride. In some embodiments, the inner spacer layer 401 may include silicon nitride, silicon oxynitride, or silicon nitride oxide. In some embodiments, the inner spacer layer 401 may be formed by, for example, chemical vapor deposition or other applicable deposition processes with a subsequent anisotropic etching process.

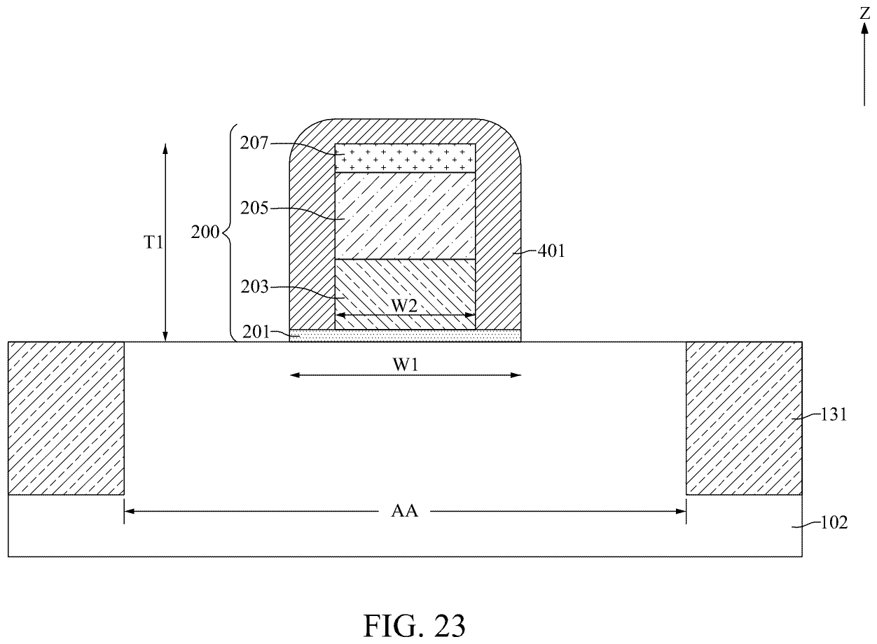

With reference to FIG. 23, an etching process may be performed using the inner spacer layer 401 as the mask to remove portions of the first insulating material 501. In some embodiments, the etching process may be an anisotropic dry etching process. The active area AA may be exposed after the etching process. The remaining first insulating material 501 may be referred to as the gate dielectric layer 201. In some embodiments, the width W1 of the gate dielectric layer 201 may be greater than the width W2 of the gate bottom conductive layer 203. The gate dielectric layer 201, the gate bottom conductive layer 203, the gate top conductive layer 205, and the gate capping layer 207 together configure the gate structure 200. In some embodiments, the thickness T1 of the gate structure 200 may be between about 70 nm and about 55 nm.

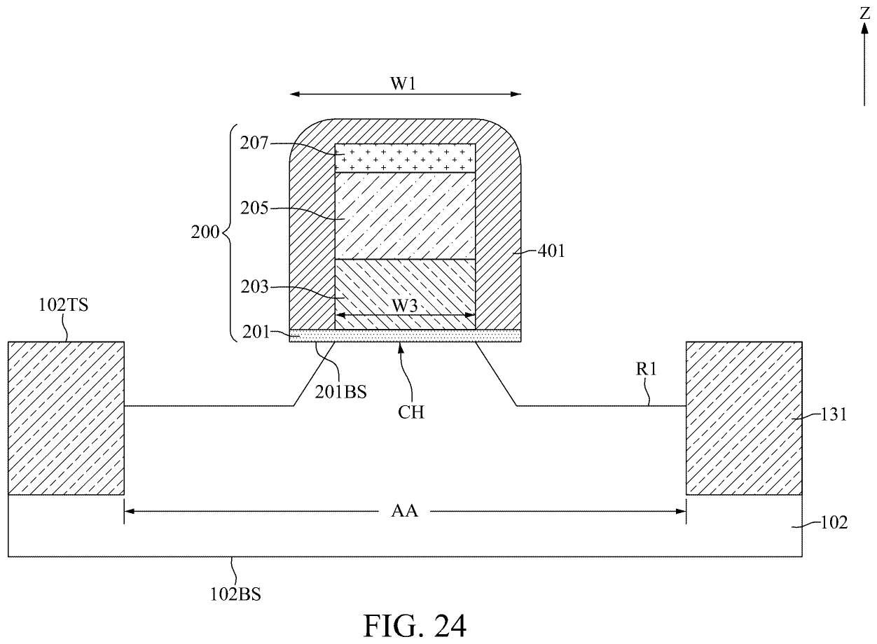

With reference to FIG. 24, an etching process may be performed to recess the active area AA to form the plurality of recesses R1. In some embodiments, the etching process may be an isotropic etching process. In some embodiments, the etching process may be a wet etching process. During the etching process, portions of the active area AA under the gate dielectric layer 201 may also be laterally etched, exposing portions of the bottom surface 201BS of the gate dielectric layer 201 through the plurality of recesses R1. In some embodiments, the plurality of recesses R1 may be formed from the top surface 102TS of the substrate 102 towards the bottom surface 102BS of the substrate 102, separated from each other, and defining a channel region CH. The channel region CH may be disposed between the plurality of recesses R1 and directly under the gate dielectric layer 201. The width W3 of the channel region CH may be less than the width W1 of the gate dielectric layer 201.

In some embodiments, the etching process may be a wet etching process including a mixture of nitric acid and hydrofluoric acid. The wet etching process may be initiated by the nitric acid, which forms a layer of silicon dioxide on the silicon (i.e., the active area AA), and the hydrofluoric acid dissolves the silicon oxide away. In some embodiments, water may be used to dilute the etchant, with acetic acid used as a buffering agent.

In some embodiments, a pre-clean process may be performed before the recessing of the plurality of recesses R1. The pre-clean process may include exposing the active area AA to a solution including a fluoride component, an oxidizing agent, and an inorganic acid.

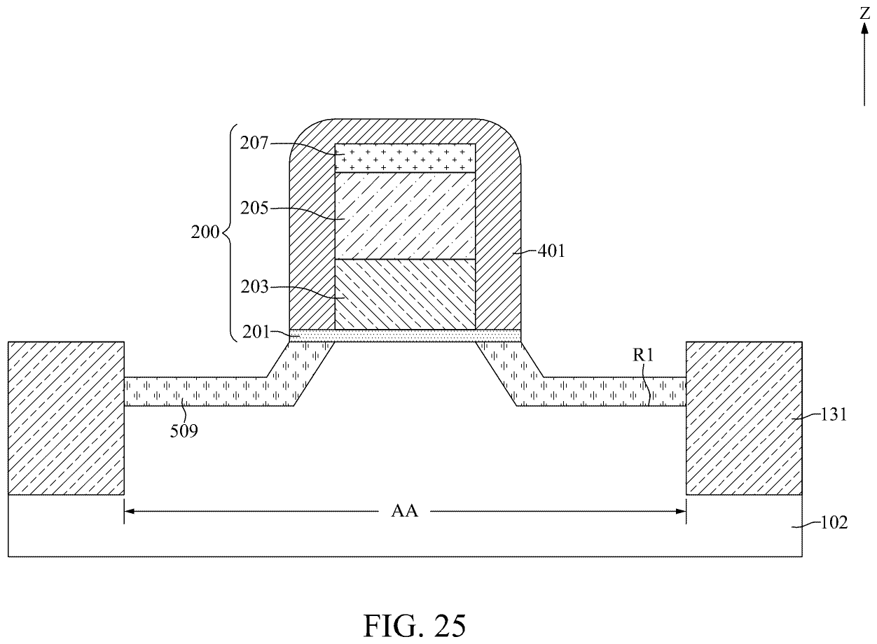

With reference to FIG. 25, the plurality of epitaxial layers 509 may be conformally formed on the active area AA and within the plurality of recesses R1. In some embodiments, the plurality of epitaxial layers 509 may include, for example, silicon, germanium, or silicon germanium. In some embodiments, the plurality of epitaxial layers 509 may be doped with n-type dopants or p-type dopants. In some embodiments, the dopant concentration of the plurality of epitaxial layers 509 may be between about 2E20 atoms/cm³ and about 4E20 atoms/cm³, or about 3E20 atoms/cm³. In some embodiments, the electrical type of the plurality of epitaxial layers 509 may be n-type or p-type, depending on the dopants doped during the formation of the plurality of epitaxial layers 509.

In some embodiments, the plurality of epitaxial layers 509 may be grown by exposing the active area AA to a radio frequency plasma from a gas flow including an etching gas. In some embodiments, the etching gas may include a halogen. In some embodiments, the etching gas may include tetrafluorosilane. In some embodiments, the flow rate of the gas flow is between about 30 standard cubic centimeters per minute (sccm) and about 40 sccm. In some embodiments, the radio frequency power of the radio frequency plasma may be between about 300 W and about 450 W. In some embodiments, the exposure of the radio frequency plasma may be between about 1 second and about 2 minutes.

In some embodiments, the plurality of epitaxial layers 509 may be formed by a deposition process that includes exposing the active area AA to a deposition gas containing at least a silicon source and a carrier gas. The deposition gas may also include a dopant source.

Detailedly, the deposition process may begin by adjusting the process chamber containing the intermediate semiconductor device illustrated in FIG. 24 to a predetermined temperature and pressure. The temperature may be tailored to the particular conducted process. In some embodiments, the process chamber may be kept at a temperature in the range from about 250° C. to about 1000° C., from about 500° C. to about 800° C., or from about 550° C. to about 750° C. The appropriate temperature to conduct the deposition process may depend on the particular precursors used to deposit the plurality of epitaxial layers 509. In some embodiments, the process chamber may be usually maintained at a pressure from about 0.1 Torr to about 200 Torr, or from about 1 Torr to about 50 Torr. The pressure may fluctuate during the deposition process but is generally maintained constant.

After the process chamber is tuned to the appropriate temperature and pressure, the intermediate semiconductor device illustrated in FIG. 24 may be exposed to the deposition gas containing the silicon source and the carrier gas to form the plurality of epitaxial layers 509. In some embodiments, the active area AA may be exposed to the deposition gas for a period of time of about 0.5 seconds to about 30 seconds, from about 1 second to about 20 seconds, or from about 5 seconds to about 10 seconds. The specific exposure time of the deposition process may be determined in relation to the particular precursors, temperature, and pressure used in the deposition process.

In some embodiments, the deposition gas for depositing the plurality of epitaxial layers 509 may include at least the silicon source and the carrier gas. In some embodiments, the deposition gas may further include a dopant compound to provide a source of dopants, such as boron, arsenic, phosphorus, gallium and/or aluminum.

In some embodiments, the silicon source may be usually provided into the process chamber at a rate in a range from about 5 sccm to about 500 sccm, from about 10 sccm to about 300 sccm, or from about 50 sccm to about 200 sccm. For example, the silicon source may be provided into the process chamber at a rate about 100 sccm.

In some embodiments, the silicon source may include silanes, halogenated silanes, and/or organosilanes.

In some embodiments, silanes may include silane (SiH₄) and higher silanes with the empirical formula SiₓH₍₂ₓ₊₂₎, such as disilane (Si₂H₆), trisilane (Si₃H₈), and tetrasilane (Si₄H₁₀), as well as others.

In some embodiments, halogenated silanes may include compounds with the empirical formula X′_{y}SiₓH_{(2x+2-y)}, where X′ is F, Cl, Br or I, such as hexachlorodisilane (Si₂Cl₆), tetrachlorosilane (SiCl₄), dichlorosilane (Cl₂SiH₂), and trichlorosilane (Cl₃SiH).

In some embodiments, organosilanes may include compounds with the empirical formula R_{y}SiₓH_{(2x+2-y)}, where R is methyl, ethyl, propyl or butyl, such as methylsilane ((CH₃)SiH₃), dimethylsilane ((CH₃)₂SiH₂), ethylsilane ((CH₃CH₂)SiH₃), methyldisilane ((CH₃)Si₂H₅), dimethyidisilane ((CH₃)₂Si₂H₄), and hexamethyldisilane ((CH₃)₆Si₂).

In the present embodiment, the silicon source may include silane, dichlorosilane, and disilane.

The silicon source may be provided into the process chamber along with the carrier gas. In some embodiments, the carrier gas may have a flow rate from about 1 slm (standard liters per minute) to about 100 slm, from about 5 slm to about 75 slm, or from about 10 slm to about 50 slm. In the present embodiment, the flow rate of the carrier gas may be, for example, about 25 slm.

The carrier gas may be selected based on the precursor (e.g., the silicon source) used and/or the process temperature during the deposition process. Usually, the carrier gas may be the same throughout the deposition process. However, some embodiments may use different carrier gases during the deposition process.

In some embodiments, the carrier gas may include nitrogen, hydrogen, argon, helium, or a combination thereof. In some embodiments, an inert carrier gas may be preferred and include nitrogen, argon, helium, and a combination thereof.

In some embodiments, nitrogen may be utilized as the carrier gas in embodiments featuring low temperature (e.g., <800° C.) processes. Nitrogen remains inert during low temperature deposition processes. Therefore, nitrogen is not incorporated into the plurality of epitaxial layers 509 during low temperature deposition processes. Also, a nitrogen carrier gas does not form hydrogen-terminated surfaces as does a hydrogen carrier gas. The hydrogen-terminated surfaces formed by the adsorption of hydrogen carrier gas on the surface inhibit the growth rate of the plurality of epitaxial layers 509. Finally, the low temperature processes may take economic advantage of nitrogen as a carrier gas, since nitrogen is far less expensive than hydrogen, argon or helium.

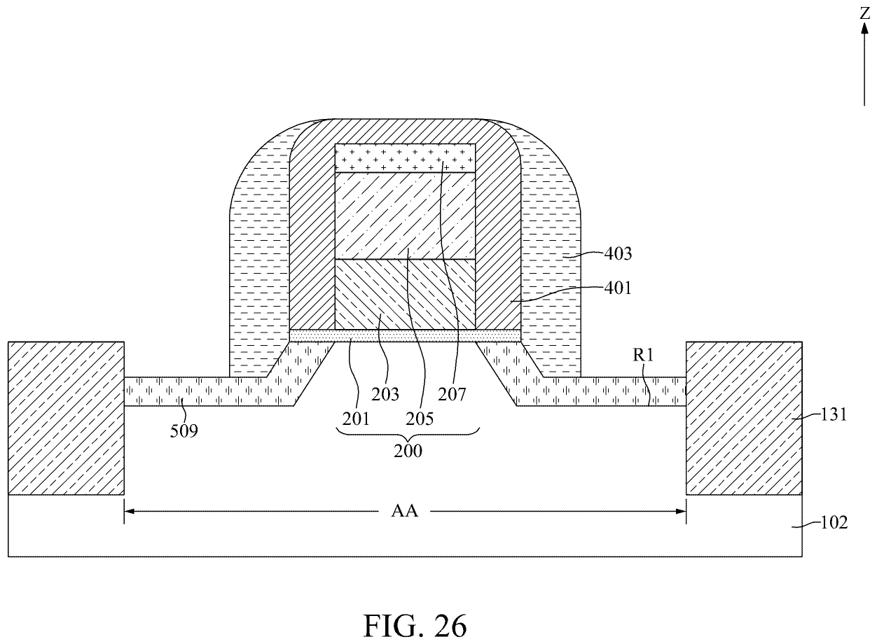

With reference to FIG. 26, the plurality of sacrificial spacer layers 403 may be conformally formed on the plurality of inner spacer layers 401, respectively and correspondingly. The plurality of sacrificial spacer layers 403 may be formed on the plurality of epitaxial layers 509. The plurality of sacrificial spacer layers 403 may be formed with a procedure similar to that illustrated in FIG. 7, and descriptions thereof are not repeated herein.

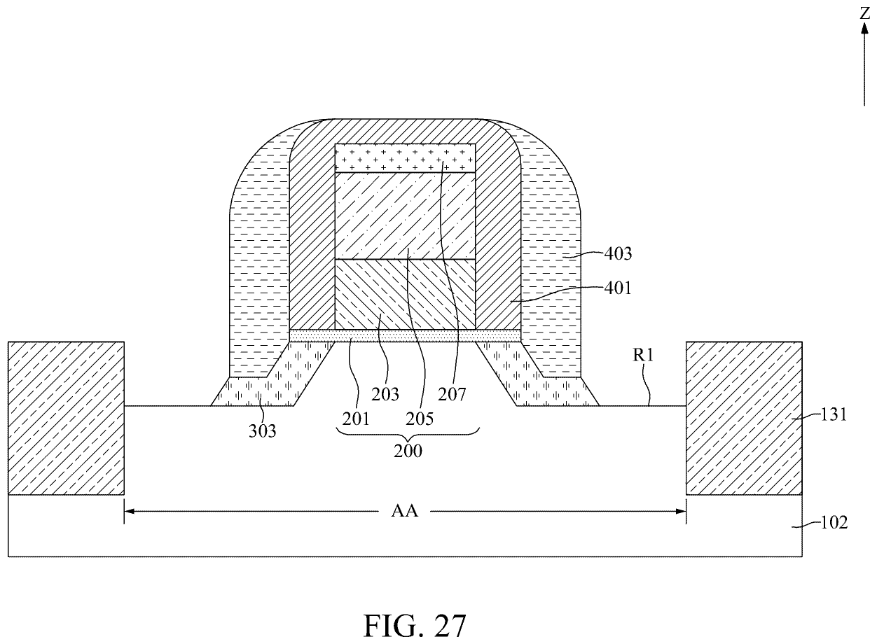

With reference to FIG. 27, an etching process may be performed using the plurality of sacrificial spacer layers 403 as the mask to remove portions of the plurality of epitaxial layers 509. During the etching process, the plurality of epitaxial layers 509 may be exposed to the etching gas for a period of time in the range from about 10 seconds to about 90 seconds, from about 20 seconds to about 60 seconds, or from about 30 seconds to about 45 seconds. After the etching process, the remaining epitaxial layers 509 may be referred to as a plurality of precursive layers 303. The plurality of precursive layers 303 may have the same electrical type as the plurality of epitaxial layers 509.

In some embodiments, the etching gas may include at least one etchant and a carrier gas. The etchant may be provided into the process chamber at a rate in the range from about 10 sccm to about 700 sccm, from about 50 sccm to about 500 sccm, or from about 100 sccm to about 400 sccm. For example, the flow rate of the etchant may be at about 200 sccm.

The etchant used in the etching gas may include chlorine, hydrogen chloride, boron trichloride, carbon tetrachloride, chlorotrifluoride, or a combination thereof.

The etchant may be usually provided into the process chamber with the carrier gas. The carrier gas may have a flow rate in the range from about 1 slm to about 100 slm, from about 5 slm to about 75 slm, or from about 10 slm to about 50 slm. For example, the flow rate of the carrier gas may be about 25 slm. In some embodiments, the carrier gas may include nitrogen, hydrogen, argon, helium, or a combination thereof.

In some embodiments, an inert carrier gas is preferred and includes nitrogen, argon, helium and combinations thereof. The carrier gas may be selected based upon specific precursor(s) and/or temperature used during the deposition of the plurality of epitaxial layers 509. The same carrier gas may be usually used during the deposition of the plurality of epitaxial layers 509 and the subsequent etching process. However, in some embodiments, different carrier gasses may be applied during the deposition of the plurality of epitaxial layers 509 and the subsequent etching process.

In some embodiments, the preferred etchant may be chlorine gas, especially when the deposition process of the plurality of epitaxial layers 509 is conducted at a low temperature (e.g., <800° C.). For example, the etching process using an etching gas containing chlorine as the etchant and nitrogen as the carrier gas may be performed at a temperature in a range from about 500° C. to about 750° C. In another example, the etching process using an etching gas containing chlorine and nitrogen may be performed at a temperature in a range from about 250° C. to about 500° C.

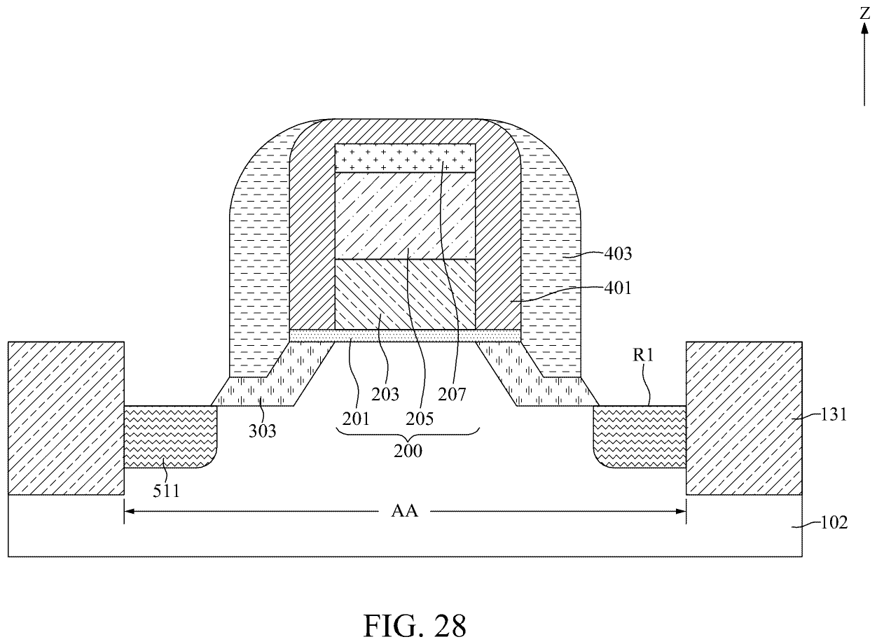

With reference to FIG. 28, an implantation process may be performed to form a plurality of pre-impurity regions 511 in the active area AA. In some embodiments, the plurality of pre-impurity regions 511 may include n-type dopants or p-type dopants. In some embodiments, the electrical type of the plurality of pre-impurity regions 511 may have the same electrical type as the plurality of precursive layers 303. The plurality of pre-impurity regions 511 may be disposed adjacent to the plurality of precursive layers 303, respectively and correspondingly.

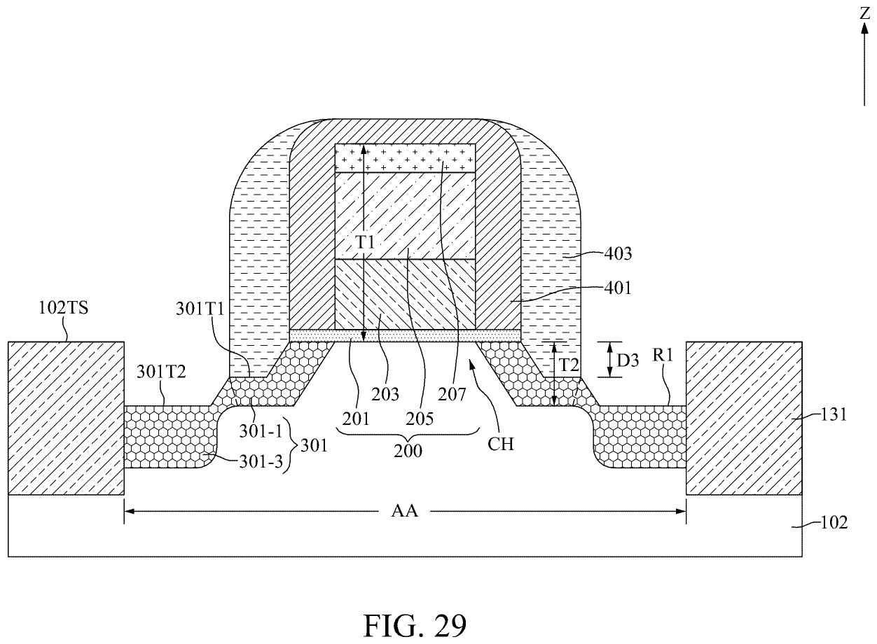

With reference to FIG. 29, the thermal treatment may be performed to activate the plurality of precursive layers 303 and the plurality of pre-impurity regions 511. In some embodiments, the temperature of the thermal treatment may be between about 800° C. and about 1250° C. In some embodiments, the thermal treatment may have a process duration between about 1 millisecond and about 500 milliseconds. In some embodiments, the thermal treatment may include, for example, a rapid thermal anneal, a laser spike anneal, or a flash lamp anneal.

After the thermal treatment, the plurality of precursive layers 303 may be turned into the plurality of lightly doped portions 301-1 and the plurality of pre-impurity regions 511 may be turned into the plurality of bulk doped portions 301-3. The plurality of lightly doped portions 301-1 and the plurality of bulk doped portions 301-3 together configure a plurality of impurity regions 301. In some embodiments, during the thermal treatment, the boundaries of the precursive layer 303 and the pre-impurity region 511 may merge and fuse together due to diffusion, forming the impurity region 301. In some embodiments, the dopant concentration of the plurality of lightly doped portions 301-1 may be less than the dopant concentration of the plurality of bulk doped portions 301-3.

In some embodiments, the plurality of lightly doped portions 301-1 may be disposed in the active area AA, and under the plurality of sacrificial spacer layers 403 and the gate dielectric layer 201. The channel region CH may be disposed between the plurality of lightly doped portions 301-1 and under the gate dielectric layer 201. In some embodiments, the thickness T2 of the plurality of lightly doped portions 301-1 may be between about 20 nm and about 25 nm. In some embodiments, the ratio of the thickness T1 of the gate structure 200 to the maximal depth D3 between the top surface 102TS of the substrate 102 and the top surface 301T1 of the plurality of lightly doped portions 301-1 may be between about 7.00 and about 3.60, between about 7.00 and about 4.60, or between about 5.50 and 3.60. In some embodiments, the ratio of the thickness T1 of the gate structure 200 to the thickness T2 of the plurality of lightly doped portions 301-1 may be between about 3.50 and about 2.20, between about 3.50 and about 2.80, or between about 2.80 and about 2.75. In some embodiments, the plurality of bulk doped portions 301-3 may be disposed in the active area AA and connect to the plurality of bulk doped portions 301-3, respectively and correspondingly. The plurality of bulk doped portions 301-3 may be exposed through the plurality of recesses R1. The top surfaces 301T1 of the plurality of lightly doped portions 301-1 and the top surfaces 301T2 of the plurality of bulk doped portions 301-3 may be coplanar with the plurality of recesses R1.

In some embodiments, the thermal treatment may be integrated in the implantation for forming the plurality of pre-impurity regions 511.

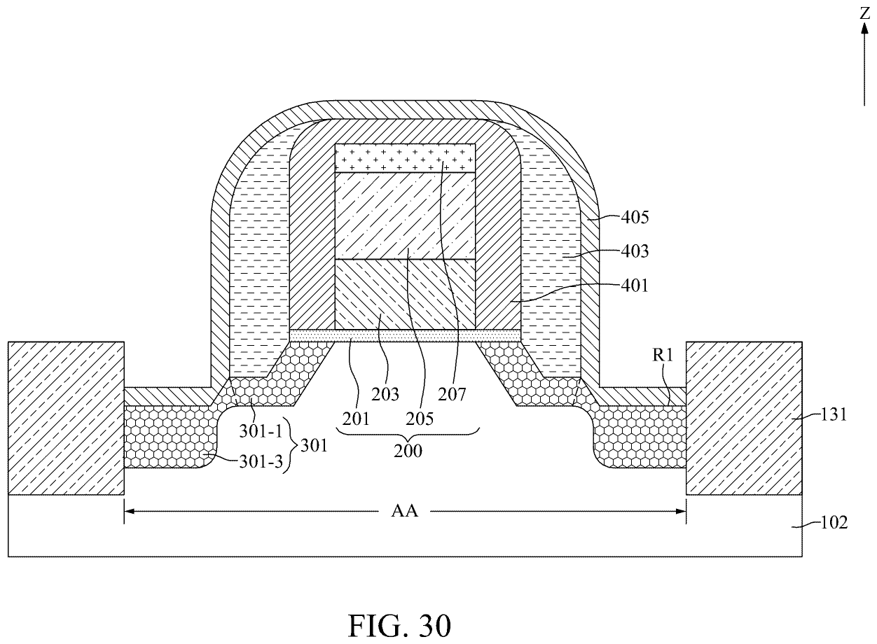

With reference to FIG. 30, the outer spacer layer 405 may be conformally formed to cover the plurality of sacrificial spacer layers 403, the inner spacer layer 401, and the plurality of bulk doped portions 301-3. Stated differently, the outer spacer layer 405 may be formed on the plurality of bulk doped portions 301-3 and enclose the plurality of sacrificial spacer layers 403 and the inner spacer layer 401. In some embodiments, the outer spacer layer 405 may be formed of the same material as the inner spacer layer 401. In some embodiments, the outer spacer layer 405 may include, for example, a nitride or an oxynitride. In some embodiments, the outer spacer layer 405 may include silicon nitride, silicon oxynitride, or silicon nitride oxide. In some embodiments, the inner spacer layer 401 may be formed by, for example, chemical vapor deposition or other applicable deposition processes with a subsequent anisotropic etching process.

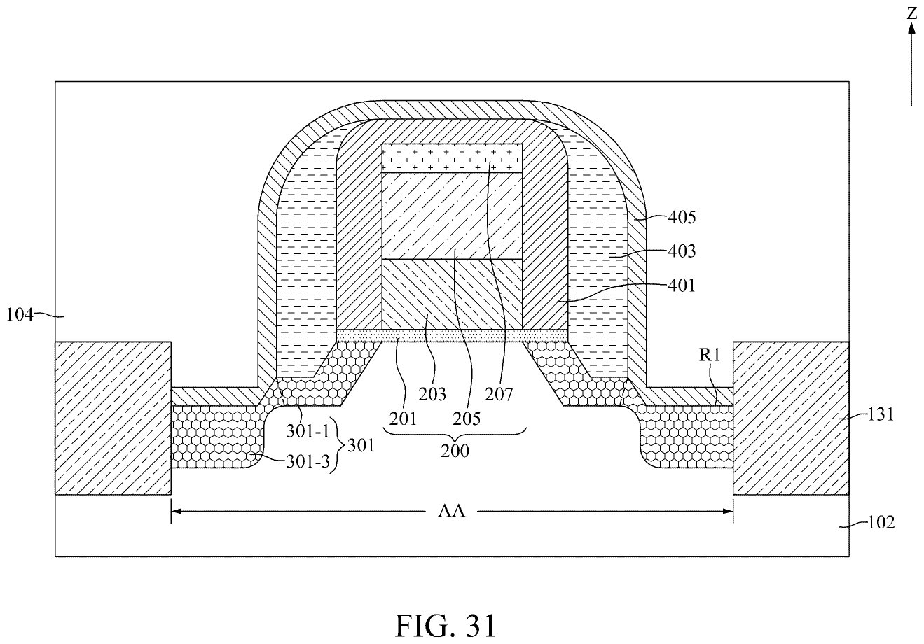

With reference to FIG. 31, a bottom dielectric layer 104 may be formed on the substrate 102 and completely covering the outer spacer layer 405. The bottom dielectric layer 104 may be formed with a procedure similar to that illustrated in FIG. 9, and descriptions thereof are not repeated herein.

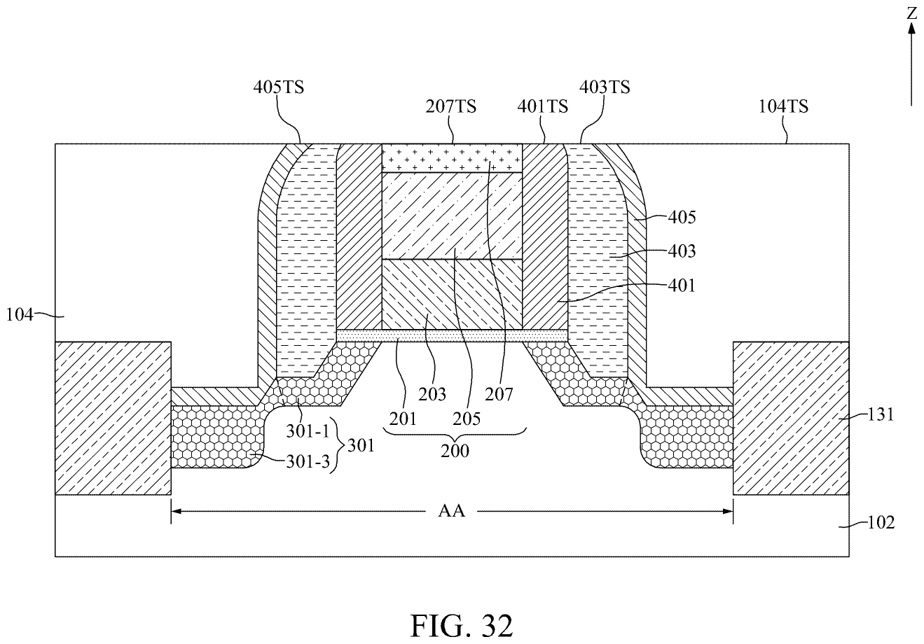

With reference to FIG. 32, a planarization process, such as chemical mechanical polishing, may be performed until the gate capping layer 207, the plurality of inner spacer layers 401, the plurality of sacrificial spacer layers 403, and the plurality of outer spacer layers 405 are exposed. In other words, the top surface 207TS of the gate capping layer 207, the top surface 401TS of the plurality of inner spacer layers 401, the top surface 403TS of the plurality of sacrificial spacer layers 403, the top surface 405TS of the plurality of outer spacer layers 405, and the top surface 104TS of the bottom dielectric layer 104 may be substantially coplanar.

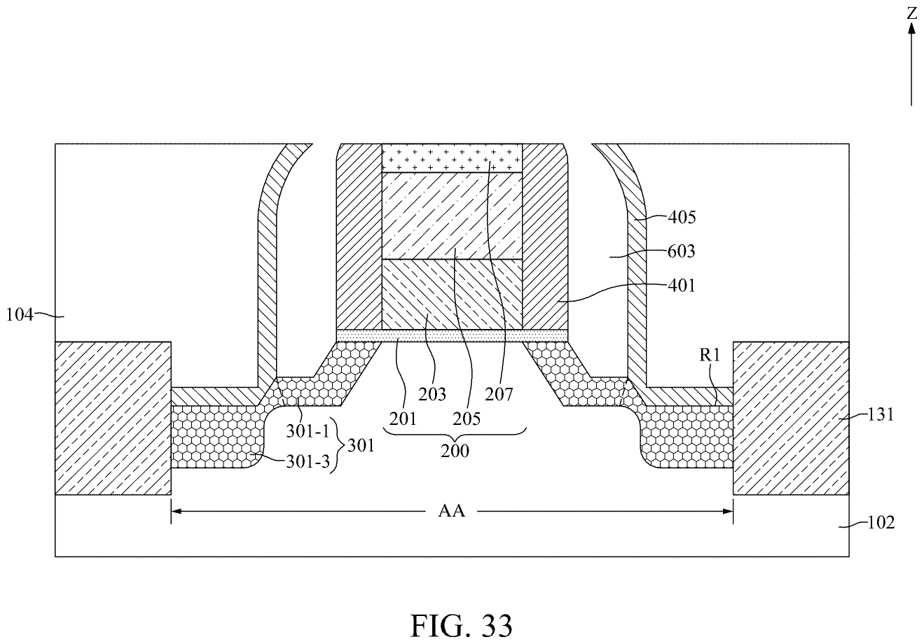

With reference to FIG. 33, the plurality of sacrificial spacer layers 403 may be removed, resulting in the formation of a plurality of temporary spaces 603 in the locations previously occupied by the sacrificial spacer layers. The removal process is similar to the procedure illustrated in FIG. 11, and descriptions thereof are not repeated herein.

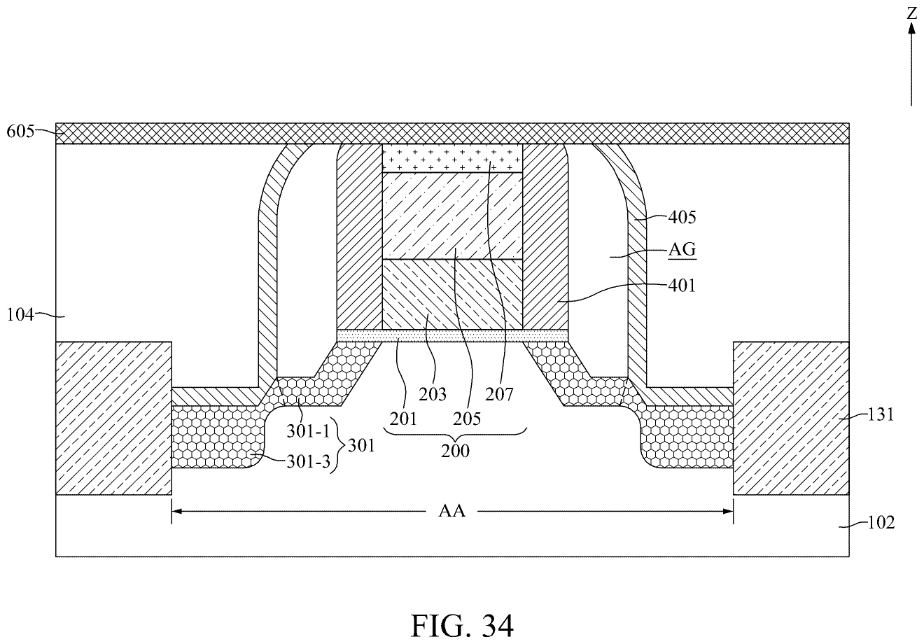

With reference to FIG. 34, the bottom capping layer 605 may be formed with a procedure similar to that illustrated in FIG. 12, and descriptions thereof are not repeated herein.

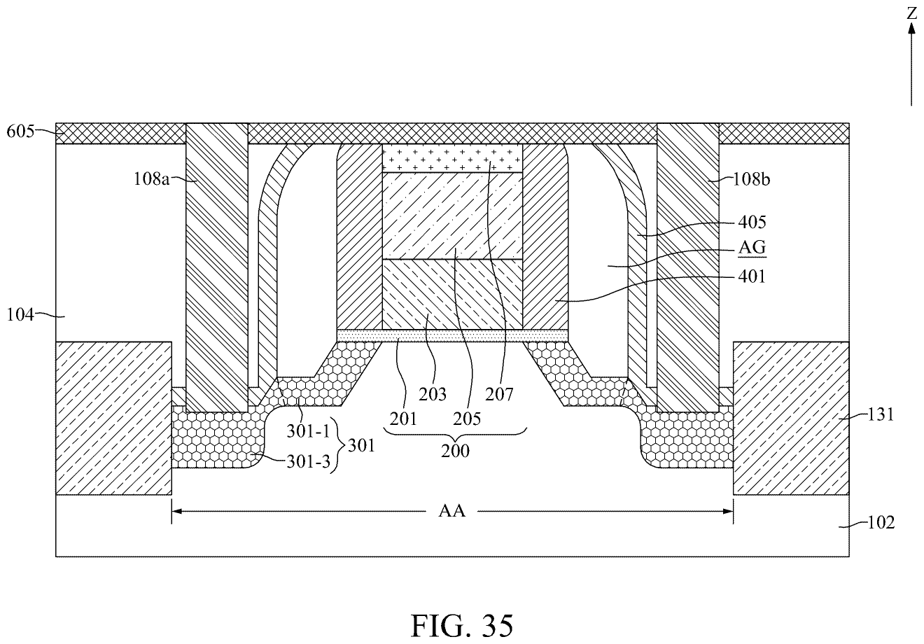

With reference to FIG. 35, the conductive elements 108a, 108b may be formed penetrating the bottom capping layer 605, the bottom dielectric layer 104, and the outer spacer layer 405. In some embodiments, the conductive elements 108a, 108b may be formed extending to the plurality of impurity regions 301, respectively and correspondingly. The conductive elements 108a, 108b may be formed with a procedure similar to that illustrated in FIG. 13, and descriptions thereof are not repeated herein.

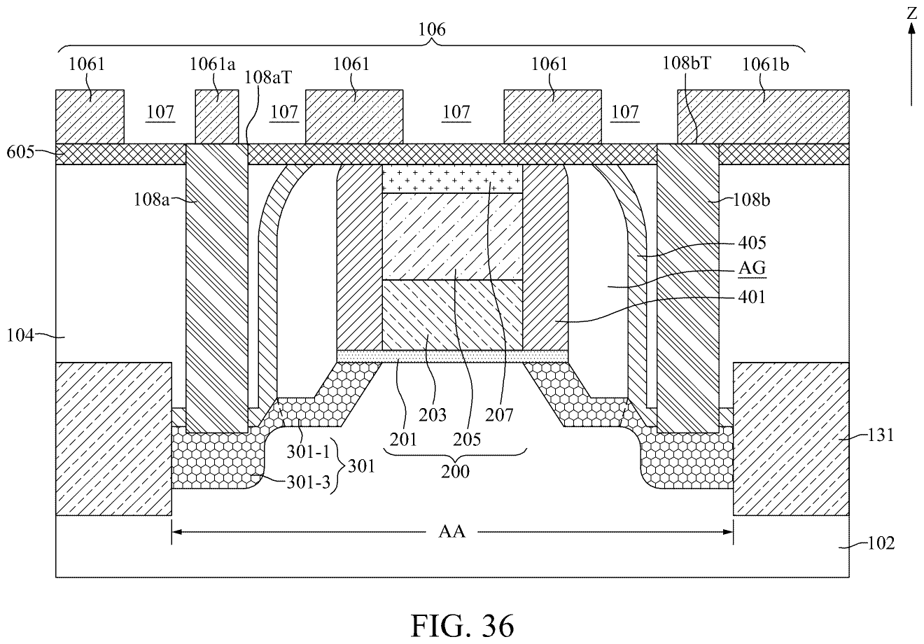

With reference to FIG. 36, the conductive layer 106 may be formed on the bottom capping layer 605 with a procedure similar to that illustrated in FIG. 14, and descriptions thereof are not repeated herein.

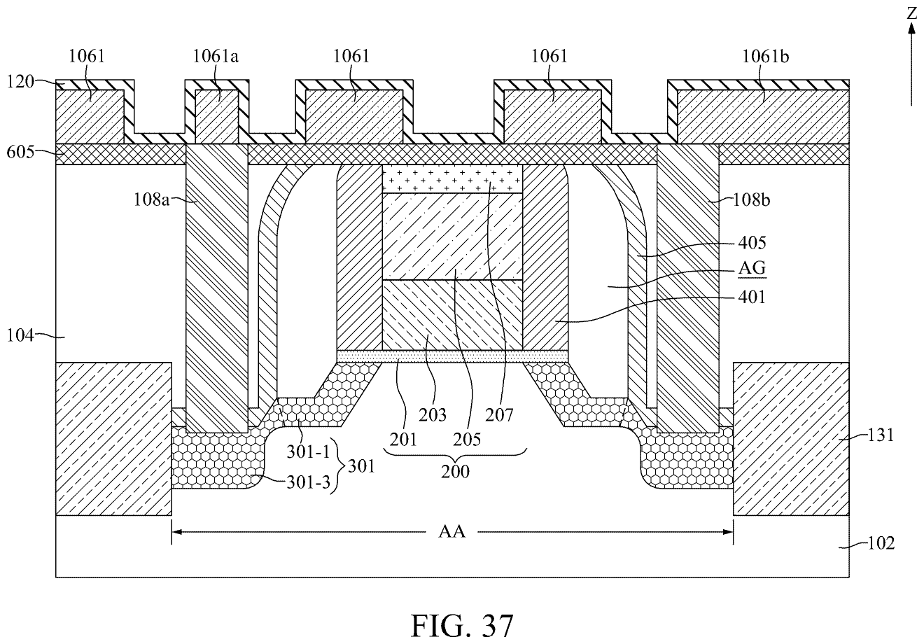

With reference to FIGS. 37 to 42, the plurality of air spacers 132 may be formed with a procedure similar to that illustrated in FIGS. 15 to 20, and descriptions thereof are not repeated herein.

The employment of the plurality of lightly doped portions 301-1 formed by epitaxial growth with tailored dopant concentration, along with substrate 102 recessing, may reduce the drain-induced barrier lowering (DIBL). This mitigation may lead to enhanced on/off ratio and reduced random dopant fluctuations, resulting in enhanced performance of semiconductor device 100B.

One aspect of the present disclosure provides a semiconductor device including a substrate; a gate structure positioned on the substrate; a plurality of inner spacer layers positioned on sidewalls of the gate structure; a plurality of outer spacer layers positioned on the plurality of inner spacer layers; a plurality of air gaps positioned between the plurality of inner spacer layers and the plurality of outer spacer layers; a bottom dielectric layer positioned on the substrate and laterally surrounding the plurality of outer spacer layers; a bottom capping layer positioned on the bottom dielectric layer, the plurality of inner spacer layers, the plurality of air gaps, the plurality of outer spacer layers, and the gate structure; a conductive layer positioned on the bottom capping layer and including a plurality of conductive wires; a top capping layer positioned on the conductive layer; and a plurality of air spacers positioned between the plurality of conductive wires.

Another aspect of the present disclosure provides a semiconductor device including a substrate and a gate structure positioned on the substrate; a plurality of inner spacer layers positioned on sidewalls of the gate structure and a plurality of outer spacer layers positioned on the plurality of inner spacer layers; a plurality of air gaps positioned between the plurality of inner spacer layers and the plurality of outer spacer layers; a plurality of recesses recessed from a top surface of the substrate, adjacent to the gate structure, and defining a channel region between the plurality of recesses and under the gate structure; a bottom dielectric layer positioned on the substrate, filling the plurality of recesses, and laterally surrounding the plurality of outer spacer layers; a bottom capping layer positioned on the bottom dielectric layer, the plurality of inner spacer layers, the plurality of air gaps, the plurality of outer spacer layers, and the gate structure; a conductive layer positioned on the bottom capping layer and including a plurality of conductive wires; a top capping layer positioned on the conductive layer; and a plurality of air spacers positioned between the plurality of conductive wires.

Another aspect of the present disclosure provides a method for fabricating a semiconductor device including providing a substrate and forming a gate structure on the substrate; forming a plurality of inner spacer layers on sidewalls of the gate structure, forming a plurality of sacrificial spacer layers on the plurality of inner spacer layers, and forming a plurality of outer spacer layers on the plurality of sacrificial spacer layers; forming a bottom dielectric layer covering the gate structure and the plurality of outer spacer layers; performing a first planarization process to expose the plurality of sacrificial spacer layers, and removing the plurality of sacrificial spacer layers to form a plurality of temporary spaces; forming a bottom capping layer on the bottom dielectric layer and sealing the plurality of temporary spaces to form a plurality of air gaps; forming a conductive layer including a plurality of conductive wires on the bottom capping layer; and forming a plurality of air spacers within the conductive layer.

Due to the design of the semiconductor device of the present disclosure, electromagnetic noise and crosstalk between the conductive lines 1061, 1061a, 1061b can be significantly reduced by the air spacers 132 formed along lateral directions (i.e., sidewalls) of the conductive wires 1061, 1061a, 1061b. In addition, electromagnetic noise and crosstalk between the gate structure 200 and the conductive elements 108a, 108b can be significantly reduced by the air gaps AG formed between the inner spacer layers 401 and the outer spacer layers 405. As a result, the performance of the semiconductor device 100A may be improved.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, and steps.

What is claimed is:

1. A semiconductor device, comprising:
a substrate and a gate structure positioned on the substrate;
a plurality of inner spacer layers positioned on sidewalls of the gate structure and a plurality of outer spacer layers positioned on the plurality of inner spacer layers;
a plurality of air gaps positioned between the plurality of inner spacer layers and the plurality of outer spacer layers;
a plurality of recesses recessed from a top surface of the substrate, adjacent to the gate structure, and defining a channel region between the plurality of recesses and under the gate structure;
a bottom dielectric layer positioned on the substrate, filling the plurality of recesses, and laterally surrounding the plurality of outer spacer layers;
a bottom capping layer positioned on the bottom dielectric layer, the plurality of inner spacer layers, the plurality of air gaps, the plurality of outer spacer layers, and the gate structure;
a conductive layer positioned on the bottom capping layer and comprising a plurality of conductive wires;
a top capping layer positioned on the conductive layer; and
a plurality of air spacers positioned between the plurality of conductive wires.

2. The semiconductor device of claim 1, further comprising a first insulating layer positioned on the bottom capping layer and between the plurality of conductive wires, wherein the plurality of air gaps are laterally surrounded by the first insulating layer.

3. The semiconductor device of claim 2, further comprising a dielectric layer positioned on the first insulating layer, wherein the plurality of air spacers are positioned between the dielectric layer and the top capping layer.

4. The semiconductor device of claim 3, further comprising a second insulating layer positioned on the dielectric layer, wherein the plurality of air gaps are laterally surrounded by the second insulating layer and the first insulating layer.

5. The semiconductor device of claim 4, wherein the bottom capping layer and the top capping layer comprise the same material.

6. The semiconductor device of claim 4, wherein the plurality of inner spacer layers and the plurality of outer spacer layers comprise the same material.

7. The semiconductor device of claim 4, further comprising a plurality of impurity regions comprising:
a plurality of lightly doped portions positioned within the substrate and separated from each other with the channel region in between; and
a plurality of bulk doped portions positioned within the substrate, respectively and correspondingly connected to the plurality of lightly doped portions.

8. The semiconductor device of claim 7, wherein a ratio of a thickness of the gate structure to a maximal depth between the top surface of the substrate and a top surface of the plurality of lightly doped portions is between about 7.00 and about 3.60.

9. The semiconductor device of claim 7, wherein the plurality of impurity regions comprises n-type dopants or p-type dopants.

10. The semiconductor device of claim 7, wherein the gate structure comprises:
a gate dielectric layer positioned on the channel region;
a gate bottom conductive layer positioned on the gate dielectric layer;
a gate top conductive layer positioned on the gate bottom conductive layer; and
a gate capping layer positioned on the gate top conductive layer.

11. The semiconductor device of claim 10, wherein a width of the gate dielectric layer is greater than a width of the gate bottom conductive layer.

12. The semiconductor device of claim 11, wherein top surfaces of the gate structure, the plurality of inner spacer layers, the plurality of outer spacer layers, and the bottom dielectric layer are substantially coplanar.

13. A method for fabricating a semiconductor device, comprising:
providing a substrate and forming a gate structure on the substrate;
forming a plurality of inner spacer layers on sidewalls of the gate structure, forming a plurality of sacrificial spacer layers on the plurality of inner spacer layers, and forming a plurality of outer spacer layers on the plurality of sacrificial spacer layers;
forming a bottom dielectric layer covering the gate structure and the plurality of outer spacer layers;
performing a first planarization process to expose the plurality of sacrificial spacer layers, and removing the plurality of sacrificial spacer layers to form a plurality of temporary spaces;
forming a bottom capping layer on the bottom dielectric layer and sealing the plurality of temporary spaces to form a plurality of air gaps;
forming a conductive layer comprising a plurality of conductive wires on the bottom capping layer; and
forming a plurality of air spacers within the conductive layer.

14. The method for fabricating the semiconductor device of claim 13, wherein removing the plurality of sacrificial spacer layers comprises a vapor etching process.

15. The method for fabricating the semiconductor device of claim 14, wherein an etchant of the vapor etching process comprises vapor hydrofluoric acid.

16. The method for fabricating the semiconductor device of claim 15, wherein the plurality of inner spacer layers comprises a carbon-containing material.

17. The method for fabricating the semiconductor device of claim 15, wherein the plurality of sacrificial spacer layers comprises doped silicon oxide.

18. The method for fabricating the semiconductor device of claim 15, wherein forming the plurality of air spacers within the conductive layer comprises:
conformally forming a first insulating layer on the plurality of conductive wires;
conformally forming a dielectric layer on the first insulating layer;
a second insulating layer may be formed covering the dielectric layer and completely filling a plurality of first gaps laterally separating the plurality of conductive wires;
performing a second planarization process to expose the plurality of conductive wires, the first insulating layer, and the dielectric layer;
partially removing the dielectric layer to form a plurality of second gaps along lateral directions of the plurality of conductive wires; and
forming a top capping layer over the conductive layer to seal the plurality of second gaps and concurrently form the plurality of air spacers.

19. The method for fabricating the semiconductor device of claim 18, wherein partially removing the dielectric layer comprises a vapor etching process.

20. The method for fabricating the semiconductor device of claim 18, wherein the bottom capping layer and the top capping layer comprises the same material.
